(19) United States
(12) Patent Application Publication
(10) Pub. No.: US 2026/0371726 A1
(43) Pub. Date: Nov. 19, 2026

(54) SEMICONDUCTOR STRUCTURE AND METHOD OF MANUFACTURING THEREOF

(71) Applicant: Taiwan Semiconductor Manufacturing Company, Ltd., Hsinchu (TW)

(72) Inventors: Ya-Chi CHOU, Hsinchu (TW); Chih-Liang CHEN, Hsinchu (TW); Chi-Yu LU, Taipei (TW); Chen-Ling WU, Taoyuan (TW); Yi-Yi CHEN, Hsinchu (TW)

(73) Assignee: Taiwan Semiconductor Manufacturing Company, Ltd., Hsinchu (TW)

(21) Appl. No.: 19/754,617

(22) Filed: Jul. 27, 2026

Related U.S. Application Data
(63) Continuation of application No. 18/965,918, filed on Dec. 2, 2024.
(60) Provisional application No. 63/690,558, filed on Sep. 4, 2024.

(51) Int. Cl. H10D 84/90

(52) U.S. Cl. CPC H10D 84/907; H10D 84/922; H10D 84/931; H10D 84/948; H10D 84/975

(57) ABSTRACT

An embodiment semiconductor structure includes a first active region and a second active region extending along a first direction, a functional gate structure and a non-functional gate structure aligned with each other and extending along a second direction, and a metallization layer over the functional gate structure and the non-functional gate structure. The metallization layer defines a first metallization region, a second metallization region, and one or two middle metallization regions between the first metallization region and the second metallization region. The functional gate structure overlaps the first metallization region and overlaps one of the one or two middle metallization regions to define an overlapped portion of the one of the one or two middle metallization regions. The overlapped portion has a space defined therein sized for a connection feature between the functional gate structure and the one of the one or two middle metallization regions.

### PRIORITY CLAIM AND CROSS-REFERENCE

This patent application is a continuation of U.S. patent application number Ser. No. 18/965,918, filed on Dec. 2, 2024, which claims the benefit of U.S. Provisional Patent Application No. 63/690,558, filed on Sep. 4, 2024, the entire disclosures of which are hereby incorporated by reference.

### BACKGROUND

The recent trend in miniaturizing integrated circuits (ICs) has resulted in smaller devices which consume less power yet provide more functionality at higher speeds. The miniaturization process has also resulted in stricter design and manufacturing specifications as well as reliability challenges. For example, IC manufacturing is directed toward reducing component sizes and cell areas to increase the number of transistors and other circuit elements in an IC die. However, the reduction of the cell areas and the increase in the density of transistors in an IC die also render the routing of interconnection structures in the IC die more complicated and challenging.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a block diagram of a semiconductor device, in accordance with some embodiments.

FIGS. 2A-2D are layout diagrams of various layout patterns corresponding to various circuit cell examples, in accordance with some embodiments.

FIGS. 3A-3D are layout diagrams of various layout patterns corresponding to various circuit cell examples, in accordance with some embodiments.

FIG. 4A is a circuit diagram of two transmission gates operable based on complementary control signals, in accordance with some embodiments.

FIGS. 4B-4D are layout diagrams of various layout patterns corresponding to a circuit cell including two transmission gates operable based on complementary control signals, in accordance with some embodiments.

FIGS. 5A-5C are layout diagrams of various layout patterns corresponding to a circuit cell including two transmission gates operable based on complementary control signals, in accordance with some embodiments.

FIG. 6A is a circuit diagram of a flip-flop circuit example, in accordance with some embodiments.

FIGS. 6B-6C are layout diagrams of various layout patterns corresponding to a circuit cell of the flip-flop circuit example of FIG. 6A, in accordance with some embodiments.

FIG. 7A is a circuit diagram of a 4:1 multiplexer circuit example, in accordance with some embodiments.

FIG. 7B is a layout diagram of various layout patterns corresponding to a circuit cell of the 4:1 multiplexer of FIG. 7A, in accordance with some embodiments.

FIGS. 8A-8D are layout diagrams of various layout patterns corresponding to circuit cell examples of a skewed logic circuit, in accordance with some embodiments.

FIG. 9 is a flowchart of a method of manufacturing a semiconductor structure, in accordance with some embodiments.

FIG. 10 is a block diagram of an electronic design automation (EDA) system in accordance with some embodiments.

FIG. 11 is a block diagram of a semiconductor device (e.g., an integrated circuit (IC)) manufacturing system, and an IC manufacturing flow associated therewith, in accordance with some embodiments.

### DETAILED DESCRIPTION

The following disclosure provides many different embodiments, or examples, for implementing different features of the provided subject matter. Specific examples of components and arrangements are described below to simplify this disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, this disclosure may repeat reference numerals and/or letters in the various examples. This repetition is for simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In addition, the term “made of” may mean either “including” or “consisting of.” In this disclosure, the phrase “one of A, B, and C” means “A, B, and/or C” (A, B, C, A and B, A and C, B and C, or A, B, and C), and does not mean one element from A, one element from B, and one element from C, unless otherwise described.

In some embodiments, a circuit cell includes three or four conductive tracks for forming signal paths at a lowest metallization layer (also referred to as M0 layer) over the transistors of the circuit cell. In some embodiments, it is challenging to minimize the routing resources used for implementation of cross-coupled transistors with a portion of gate structures configured as non-functional gate structures. In some embodiments, forming one or more non-functional gate structures and corresponding one or more aligned functional gate structures based on a shortened continuous-poly-on-oxide-diffusion-edge (CPODE) pattern and/or a shifted cut-poly (CPO) as further illustrated in this disclosure makes available more options for landing a gate via structure. Accordingly, in some embodiments, one or more benefits of manufacturing a semiconductor structure based on a shortened CPODE pattern and/or a shifted CPO pattern include increasing flexibility of layout routing, reducing routing complexity and hence reducing unintended signal coupling, increasing a number of vias connecting a gate structure to a same conductive track to reduce resistance, reducing a number of dummy devices in a circuit cell of a skewed logic circuit, or any combination thereof.

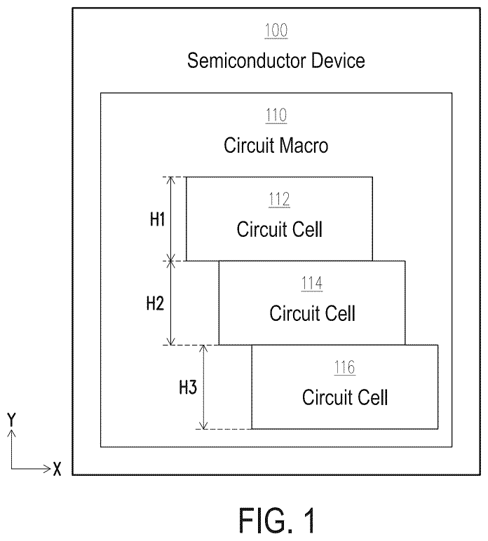

FIG. 1 is a block diagram of a semiconductor device 100, in accordance with some embodiments of the present disclosure. In some embodiments, semiconductor device 100 corresponds to a portion of an integrated circuit (IC).

As in FIG. 1, semiconductor device 100 includes, among other things, at least one circuit macro 110. In some embodiments, circuit macro 110 corresponds to a set of semiconductor components configured as a memory, a controller, one or more logic gates, or the like. Circuit macro 110 includes, among other things, one or more circuit cells, such as circuit cell 112, circuit cell 114, and circuit cell 116. In some embodiments, each of the circuit cells 112, 114, and 116 include transistors formed based on one or more active regions extending along a first direction (e.g., the X direction) and one or more gate structures extending along a second direction (e.g., the Y direction). In some embodiments, each of the circuit cells 112, 114, and 116 has a corresponding cell height H1, H2, and H3 measurable along the second direction.

In some embodiments, each of the circuit cells 112, 114, and 116 include respective conductive tracks within one or more metallization layers and electrically connecting various transistors within each one of the circuit cells 112, 114, and 116. In some embodiments, the semiconductor device 100 defines multiple power track regions extending along the first direction configured to carry a first supply voltage (e.g., VDD) or a second supply voltage (e.g., VSS or ground). In some embodiments, a circuit cell includes a first side extending along a power track region and a second side extending along another power track region. In some embodiments, a circuit cell that does not have any other power track region between the first side and the second side thereof is sometimes referred to as having a standard cell height. In some embodiments for a more compact design based on some processing nodes, a circuit cell having a standard cell height includes up to four metallization regions (other than the power track regions) extending along the first direction in a lowest metallization layer (also referred to as M0 layer) over the transistors of the circuit cell. In some embodiments, any of the cell height H1, H2, and H3 has a standard cell height (e.g., a 1 H cell), two standard cell heights (e.g., a 2 H cell), three standard cell heights (e.g., a 3 H cell). In some embodiments, a cell in the circuit macro 110 corresponds to multiple standard cell heights or less than one standard cell height (e.g., a ½ H cell).

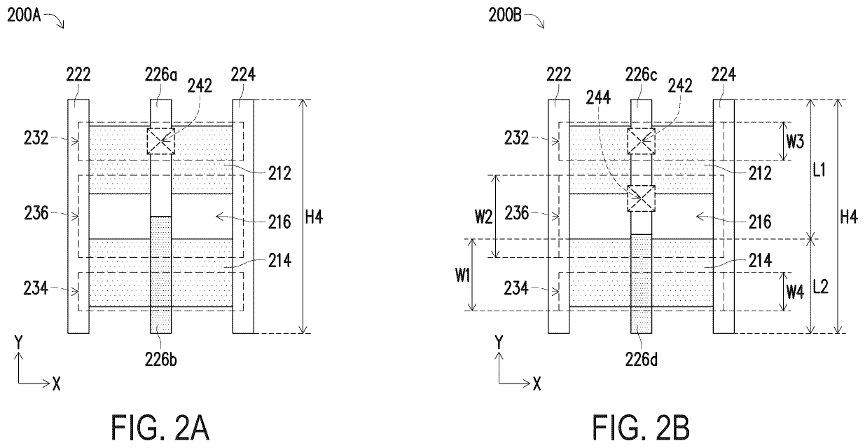

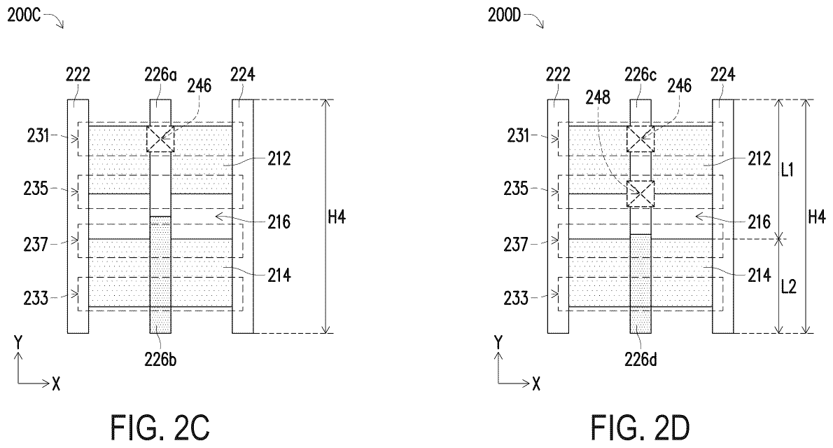

FIG. 2A is a layout diagram 200A of various layout patterns corresponding to a portion of a first circuit cell example, in accordance with some embodiments. In some embodiments, the first circuit cell example is a portion of a semiconductor device, such as the semiconductor device 100 in FIG. 1.

Layout diagram 200A depicts a first active region pattern 212 indicative of a first active region of the semiconductor device extending along a first direction (e.g., the X direction); and a second active region pattern 214 indicative of a second active region of the semiconductor device extending along the first direction (e.g., the X direction). In some embodiments, an isolation region 216 is between and adjoining the first active region and the second active region as indicated by a blank region 216 between first active region pattern 212 and second active region pattern 214. In some embodiments, one of the first active region and the second active region is for forming one or more p-type transistors; and the other one of the first active region and the second active region is for forming one or more n-type transistors.

Layout diagram 200A also includes a first gate pattern 222, a second gate pattern 224, a third gate pattern 226a, and a fourth gate pattern 226b. Each of first gate pattern 222 and second gate pattern 224 is indicative of one or more functional gate structures or non-functional gate structures extending along a second direction (e.g., the Y direction). Third gate pattern 226a is between first gate pattern 222 and second gate pattern 224 and is indicative of a functional gate structure extending along the second direction (e.g., the Y direction) and overlapping the first active region (e.g., overlapping throughout at least an entire width of the first active region along the second direction). Fourth gate pattern 226b is also between first gate pattern 222 and second gate pattern 224 and is indicative of a non-functional gate structure extending along the second direction (e.g., the Y direction), aligned with the functional gate structure indicated by third gate pattern 226a along the second direction, and overlapping the second active region (e.g., overlapping throughout at least an entire width of the second active region along the second direction).

In some embodiments, a transistor is formed based on one of the active regions and a corresponding gate structure overlapping therewith. For example, one or more channel structures are formed within the first active region (e.g., indicated by first active region pattern 212) overlapping with a functional gate structure (e.g., indicated by third gate pattern 226a). In some embodiments, the one or more channel structures being under or surrounded by the functional gate structure. In some embodiments, a first drain/source structure is formed within the active region and on a first side of the functional gate structure; and a second drain/source structure is formed within the active region and on a second side of the functional gate structure. In some embodiments, a combination of the functional gate structure, the one or more channel structures, the first drain/source structure, and the second drain/source structure correspond to a planar field effect transistor (FET), a fin FET (FinFET), a nanosheet FET, a nanowire FET, or a complementary FET (CFET).

In layout diagram 200A, the first circuit cell example has a cell height of H4. In some embodiments, the first circuit cell example includes a metallization layer over the functional gate structure and the non-functional gate structure. In some embodiments, the metallization layer is a lowest metallization layer of one or more metallization layers of the first circuit cell example over the functional gate structure and the non-functional gate structure, and is sometimes known as an M0 layer of the first circuit cell example. As a non-limiting example, the first circuit cell example of layout diagram 200A has three metallization regions in the M0 layer. Layout diagram 200A includes a first metallization track pattern 232, a second metallization track pattern 234, and a third metallization track pattern 236 corresponding to various metallization regions defined in the metallization layer. For example, first metallization track pattern 232 is indicative of a first metallization region extending along the first direction (e.g., the X direction) over the first active region; second metallization track pattern 234 is indicative of a second metallization region extending along the first direction (e.g., the X direction) over the second active region, and third metallization track pattern 236 is indicative of a third metallization region extending along the first direction (e.g., the X direction) and between the first metallization region and the second metallization region.

In FIG. 2A as a non-limiting example, the non-functional gate structure indicated by fourth gate pattern 226b is formed based on a continuous-poly-on-oxide-diffusion-edge (CPODE) process to form the non-functional gate structure that is a dielectric gate structure adjoining the functional gate structure indicated by third gate pattern 226a. In some embodiments, the fourth gate pattern 226b is also a CPODE pattern for forming the corresponding non-functional gate structure, and the third gate pattern 226a is defined based on subtracting the fourth gate pattern 226b from a gate pattern extending throughout at least the entire cell height H4. In this example, the boundary between third gate pattern 226a and fourth gate pattern 226b is arranged at about the middle between the first active region indicated by first active region pattern 212 and the second active region indicated by second active region pattern 214. In FIG. 2A, if the functional gate structure indicated by third gate pattern 226a is to be electrically connected to a conductive track of the metallization layer (e.g., the M0 layer), the only option in some embodiments is through a connection feature (e.g., a via structure) indicated by a via pattern 242 connecting the functional gate structure and a conductive track formed based on the first metallization region indicated by first metallization track pattern 232.

FIG. 2B is a layout diagram 200B of various layout patterns corresponding to a portion of a second circuit cell example, in accordance with some embodiments. The second circuit cell example is a modification based on the first circuit cell example. Therefore, components depicted in FIG. 2A that are the same or similar to those in FIG. 2A are given the same reference numbers, and detailed description thereof is simplified or omitted.

Compared with layout diagram 200A, layout diagram 200B includes a modified third gate pattern 226c indicative of a functional gate structure of the second circuit cell example and a modified fourth gate pattern 226d indicative of a non-functional gate structure of the second circuit cell example. Compared with the example of FIG. 2A, a length L1 of the modified third gate pattern 226c is greater than a length of the third gate pattern 226a; and a length L2 of the modified fourth gate pattern 226d is less than a length of the fourth gate pattern 226b (i.e., the modified fourth gate pattern 226d being a shortened CPODE pattern). Accordingly, the functional gate structure indicated by the modified third gate pattern 226c overlaps the first metallization region indicated by first metallization track pattern 232 and overlaps the third metallization region indicated by third metallization track pattern 236. In some embodiments, a length of the non-functional gate structure (e.g., indicated by length L2 of modified fourth gate pattern 226d) within a cell region of the second circuit cell example, and measurable along the second direction, is equal to or greater than a width of the second active region (e.g., indicated by width W1 of second active region pattern 214) measurable along the second direction. In some embodiments, the length of the non-functional gate structure (e.g., L2) along the second direction is less than one-half of a cell height of the cell region along the second direction (e.g., one-half of H4).

In some embodiments, the functional gate structure overlaps the third metallization region to define an overlapped portion of the third metallization region, and the overlapped portion of the third metallization region has a space defined therein sized for a connection feature between the functional gate structure and the third metallization region (e.g., the space as indicated by another via pattern 244). In FIG. 2B, if the functional gate structure indicated by modified third gate pattern 226c is to be electrically connected to a conductive track of the metallization layer (e.g., the M0 layer), there are two options in some embodiments, including: connecting the functional gate structure and a conductive track formed based on the first metallization region indicated by first metallization track pattern 232 through a connection feature (e.g., a via structure) indicated by via pattern 242; and connecting the functional gate structure and a conductive track formed based on the third metallization region indicated by third metallization track pattern 236 through a connection feature (e.g., a via structure) indicated by via pattern 244.

In some embodiments, a width of the third metallization region (e.g., indicated by width W2 of third metallization track pattern 236) is 1.2 to 2 times a width of the first metallization region (e.g., indicated by width W3 of first metallization track pattern 232). In some embodiments, the width of the third metallization region (e.g., W2) is 1.2 to 2 times a width of the second metallization region (e.g., indicated by width W4 of second metallization track pattern 234). In some embodiments, the width of the first metallization region (e.g., W3) and the width of the second metallization region (e.g., W4) are substantially the same (e.g., having a variation within 10% of a nominal width).

In some embodiments, compared to the first circuit cell example in FIG. 2A, the second circuit cell example in FIG. 2B with a shortened CPODE pattern (e.g., fourth gate pattern 226b versus modified fourth gate pattern 226d) enables additional option(s) for landing a via between a functional gate structure and a conductive track at the M0 layer (e.g., one via pattern 242 in FIG. 2A versus two via patterns 242 and 244 in FIG. 2B). In some embodiments, one or more benefits of implementing a shortened CPODE pattern and increasing options for landing a via include increasing flexibility of layout routing, reducing routing complexity and hence reducing unintended signal coupling, increasing a number of vias connecting a gate structure to a same conductive track to reduce resistance, reducing a number of dummy devices in a circuit cell of a skewed logic circuit, or any combination thereof.

FIG. 2C is a layout diagram 200C of various layout patterns corresponding to a portion of a third circuit cell example, in accordance with some embodiments. The third circuit cell example is a variation of the first circuit cell example. Therefore, components depicted in FIG. 2C that are the same or similar to those in FIG. 2A are given the same reference numbers, and detailed description thereof is simplified or omitted.

Compared with layout diagram 200A, layout diagram 200C includes the third circuit cell example that has a cell height of H4 and four metallization regions in an M0 layer of the third circuit cell example, indicated by four metallization track patterns 231, 233, 235, and 237 indicative of four respective metallization regions extending along the first direction (e.g., the X direction). In some embodiments, the widths of the metallization regions indicated by the metallization track patterns 231, 233, 235, and 237 are substantially the same (e.g. having a variation within 10% of a nominal width). In this example, the boundary between third gate pattern 226a and fourth gate pattern 226b is arranged at about the middle between the first active region indicated by first active region pattern 212 and the second active region indicated by second active region pattern 214.

As in FIG. 2C, if the functional gate structure indicated by third gate pattern 226a is to be electrically connected to a conductive track of the metallization layer (e.g., the M0 layer), the only feasible option in some embodiments is through a connection feature (e.g., a via structure) indicated by a via pattern 246 connecting the functional gate structure and a conductive track formed based on the first metallization region indicated by first metallization track pattern 231. In some embodiments as in FIG. 2C, while third gate pattern 226a overlaps metallization track pattern 235, the boundary between third gate pattern 226a and fourth gate pattern 226b is too close to metallization track pattern 235 and thus renders formation of a via structure landing on a conductive track based on metallization track pattern 235 susceptible to process variations. As such, a via structure for connecting the functional gate structure (e.g., indicated by third gate pattern 226a) and a conductive track based on metallization track pattern 235 is not feasible or practical.

FIG. 2D is a layout diagram 200D of various layout patterns corresponding to a portion of a fourth circuit cell example, in accordance with some embodiments. The fourth circuit cell example is a modification based on the third circuit cell example in view of the second circuit cell example. Therefore, components depicted in FIG. 2D that are the same or similar to those in FIGS. 2A-2C are given the same reference numbers, and detailed description thereof is simplified or omitted.

Compared with layout diagram 200C, layout diagram 200D includes modified third gate pattern 226c and modified fourth gate pattern 226d as in FIG. 2B. Compared with the example in FIG. 2C, a length L1 of modified third gate pattern 226c is greater than a length of third gate pattern 226a; and a length L2 of modified fourth gate pattern 226d is less than a length of the fourth gate pattern 226b. Accordingly, in some embodiments, the functional gate structure indicated by modified third gate pattern 226c overlaps the first metallization region indicated by first metallization track pattern 231 and overlaps the third metallization region indicated by third metallization track pattern 235. In some embodiments, the length of the non-functional gate structure (e.g., length L2) within a cell region of the fourth circuit cell example, a width of the second active region, and a cell height of the cell region (e.g., H4) along the second direction have relationships as described in connection with FIG. 2B.

In some embodiments, the functional gate structure (e.g., indicated by modified third gate pattern 226c) overlaps a metallization region indicated by metallization track pattern 231 sufficient to define via pattern 246. In some embodiments, the functional gate structure (e.g., indicated by modified third gate pattern 226c) further overlaps a metallization region indicated by metallization track pattern 235 to define an overlapped portion having a space defined therein sized for a connection feature between the functional gate structure and the corresponding metallization region (e.g., indicated by via pattern 248). In some embodiments as in FIG. 2D, as the boundary between modified third gate pattern 226c and modified fourth gate pattern 226d is moved farther away from the first active region indicated by first active region pattern 212, formation of a via structure based on via pattern 248 is much less susceptible to process variations than the example of FIG. 2C and thus becomes a feasible or practical option.

Accordingly, as in FIG. 2D, if the functional gate structure indicated by modified third gate pattern 226c is to be electrically connected to a conductive track of the metallization layer (e.g., the M0 layer), there are two options in some embodiments, including: connecting the functional gate structure and a conductive track formed based on the first metallization region indicated by first metallization track pattern 231 through a connection feature (e.g., a via structure) indicated by via pattern 246; and connecting the functional gate structure and a conductive track formed based on the third metallization region indicated by third metallization track pattern 235 through a connection feature (e.g., a via structure) indicated by via pattern 248. In some embodiments, compared to the third circuit cell example in FIG. 2C, the fourth circuit cell example in FIG. 2D with a shortened CPODE pattern (e.g., fourth gate pattern 226b versus modified fourth gate pattern 226d) has the options and benefits similar to those discussed with reference to FIG. 2B.

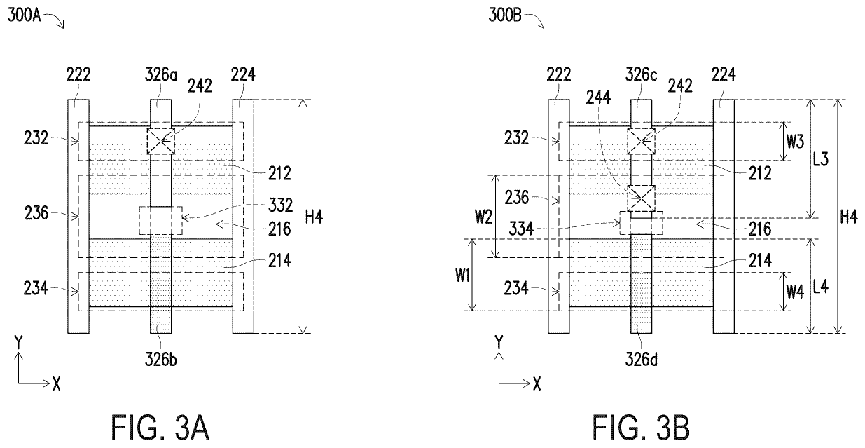

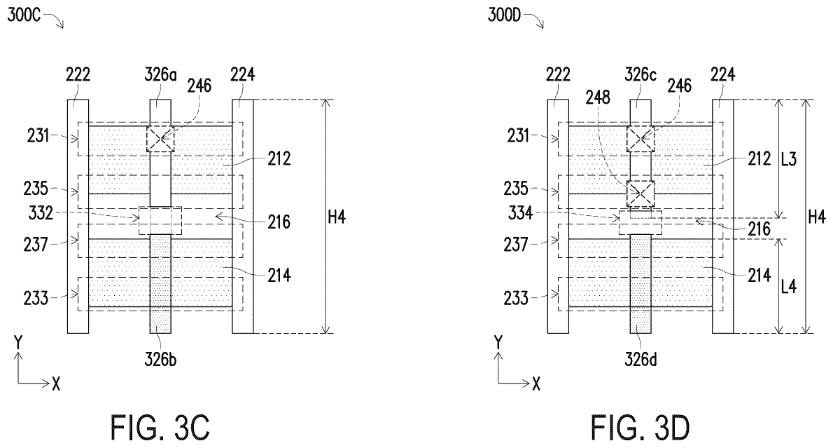

FIG. 3A is a layout diagram 300A of various layout patterns corresponding to a portion of a fifth circuit cell example, in accordance with some embodiments. The fifth circuit cell example is a variation of the first circuit cell example. Therefore, components depicted in FIG. 3A that are the same or similar to those in FIG. 2A are given the same reference numbers, and detailed description thereof is simplified or omitted. In some embodiments, layout diagram 300A includes the fifth circuit cell example that has a cell height of H4 and three metallization regions in an M0 layer of the fifth circuit cell example.

Compared with layout diagram 200A, layout diagram 300A includes a fifth gate pattern 326a and a sixth gate pattern 326b. Fifth gate pattern 326a is between first gate pattern 222 and second gate pattern 224 and is indicative of a functional gate structure extending along the second direction (e.g., the Y direction) and overlapping the first active region. Sixth gate pattern 326b is also between first gate pattern 222 and second gate pattern 224 and is indicative of a non-functional gate structure extending along the second direction (e.g., the Y direction), aligned with the functional gate structure along the second direction, and overlapping the second active region.

In FIG. 3A as a non-limiting example, the non-functional gate structure indicated by sixth gate pattern 326b is formed based on a cut-poly (CPO) process, where the non-functional gate structure is implemented as a dielectric gate structure or a conductive gate structure, and spaced apart from the functional gate structure. In some embodiments, the CPO process is performed based on a CPO pattern 332 separating a gate pattern extending throughout the entire cell height H4 into fifth gate pattern 326a and sixth gate pattern 326b. In this example, CPO pattern 332 is arranged at about the middle between the first active region indicated by first active region pattern 212 and the second active region indicated by second active region pattern 214.

In FIG. 3A, if the functional gate structure indicated by fifth gate pattern 326a is to be electrically connected to a conductive track of the metallization layer (e.g., the M0 layer), the only feasible option in some embodiments is through a connection feature (e.g., a via structure) indicated by a via pattern 242 connecting the functional gate structure and a conductive track formed based on the first metallization region indicated by first metallization track pattern 232. In some embodiments as in FIG. 3A, while fifth gate pattern 326a overlaps metallization track pattern 236, the corresponding overlapped space is insufficient to accommodate a via pattern therein.

FIG. 3B is a layout diagram 300B of various layout patterns corresponding to a portion of a sixth circuit cell example, in accordance with some embodiments. The sixth circuit cell example is a modification based on the fifth circuit cell example. Therefore, components depicted in FIG. 3B that are the same or similar to those in FIG. 3A are given the same reference numbers, and detailed description thereof is simplified or omitted.

Compared with layout diagram 300A, layout diagram 300B includes a modified fifth gate pattern 326c indicative of a functional gate structure of the sixth circuit cell example and a modified sixth gate pattern 326d indicative of a non-functional gate structure of the sixth circuit cell example. In some embodiments, modified fifth gate pattern 326c and modified sixth gate pattern 326d are defined based on a CPO pattern 334 separating a gate pattern extending throughout the entire cell height H4 into modified fifth gate pattern 326c and modified sixth gate pattern 326d. Compared with the example in FIG. 3A, the CPO pattern 334 is moved farther away from the first active region pattern 212. In some embodiments, a length L3 of modified fifth gate pattern 326c is greater than a length of fifth gate pattern 326a; and a length L4 of modified sixth gate pattern 326d is less than a length of sixth gate pattern 226b. Accordingly, in some embodiments, the functional gate structure indicated by the modified third gate pattern 226c overlaps the first metallization region indicated by first metallization track pattern 232 and overlaps the third metallization region indicated by third metallization track pattern 236. In some embodiments, a length of the non-functional gate structure (e.g., indicated by length L4 of modified sixth gate pattern 326d) within a cell region of the sixth circuit cell example and measurable along the second direction is equal to or greater than a width of the second active region (e.g., indicated by width W1 of second active region pattern 214) measurable along the second direction. In some embodiments, the length of the non-functional gate structure (e.g., L4) along the second direction is less than one-half of a cell height of the cell region along the second direction (e.g., one-half of H4).

In some embodiments, the functional gate structure overlaps the third metallization region to define an overlapped portion of the third metallization region, and the overlapped portion of the third metallization region has a space defined therein sized for a connection feature between the functional gate structure and the third metallization region (e.g., indicated by another via pattern 244). With reference to FIG. 2B, in some embodiments, a width of the third metallization region (e.g., W2) is 1.2 to 2 times a width of the first metallization region (e.g., W3). In some embodiments, a width of the third metallization region (e.g., W2) is 1.2 to 2 times a width of the second metallization region (e.g., W4). In some embodiments, the width of the first metallization region (e.g., W3) and the width of the second metallization region (e.g., W4) are substantially the same (e.g., having a variation within 10% of a nominal width).

As in FIG. 3B and similarly with reference to FIG. 2B, if the functional gate structure indicated by modified fifth gate pattern 326c is to be electrically connected to a conductive track of the metallization layer (e.g., the M0 layer), there are two options in some embodiments, including connecting the functional gate structure and a conductive track formed based on the first metallization region indicated by first metallization track pattern 232 through a connection feature (e.g., a via structure) indicated by via pattern 242 and connecting the functional gate structure and a conductive track formed based on the third metallization region indicated by third metallization track pattern 236 through a connection feature (e.g., a via structure) indicated by via pattern 244. In some embodiments, compared to the fifth circuit cell example in FIG. 3A, the sixth circuit cell example in FIG. 3B with a shifted CPO pattern (e.g., CPO pattern 334 versus CPO pattern 332) provides options and benefits similar to those discussed with reference to FIG. 2B.

FIG. 3C is a layout diagram 300C of various layout patterns corresponding to a portion of a seventh circuit cell example, in accordance with some embodiments. In some embodiments, the seventh circuit cell example is a variation of the fifth circuit cell example. Therefore, components depicted in FIG. 3C that are the same or similar to those in FIG. 3A are given the same reference numbers, and detailed description thereof is simplified or omitted.

Compared with layout diagram 300A, layout diagram 300C includes the seventh circuit cell example that has a cell height of H4 and four metallization region in an M0 layer of the seventh circuit cell example, including four metallization track patterns 231, 233, 235, and 237 indicative of four respective metallization regions extending along the first direction (e.g., the X direction). In some embodiments, the widths of the metallization regions indicated by the metallization track patterns 231, 233, 235, and 237 are substantially the same (e.g., having a variation within 10% of a nominal width). In this example, CPO pattern 332 is arranged at about the middle between the first active region indicated by first active region pattern 212 and the second active region indicated by second active region pattern 214.

As in FIG. 3C, if the functional gate structure indicated by fifth gate pattern 326a is to be electrically connected to a conductive track of the metallization layer (e.g., the M0 layer), the only option in some embodiments is through a connection feature (e.g., a via structure) indicated by a via pattern 246 connecting the functional gate structure and a conductive track formed based on the first metallization region indicated by first metallization track pattern 231. In some embodiments as in FIG. 3C, while fifth gate pattern 326a overlaps metallization track pattern 235, the boundary between fifth gate pattern 326a and sixth gate pattern 326b is too close to metallization track pattern 235 and thus renders formation of a via structure landing on a conductive track based on metallization track pattern 235 susceptible to process variations. As such, a via structure for connecting the functional gate structure (e.g., indicated by fifth gate pattern 326a) and a conductive track based on metallization track pattern 235 is not feasible or practical.

FIG. 3D is a layout diagram 300D of various layout patterns corresponding to a portion of an eighth circuit cell example, in accordance with some embodiments. The eighth circuit cell example is a modification based on the seventh circuit cell example in view of the sixth circuit cell example. Therefore, components depicted in FIG. 3D that are the same or similar to those in FIGS. 3A-3C are given the same reference numbers, and detailed description thereof is simplified or omitted.

Compared with layout diagram 300C, layout diagram 300D includes modified fifth gate pattern 326c and modified sixth gate pattern 326d as in FIG. 3B. Compared with the example in FIG. 3C, a length L3 of modified fifth gate pattern 326c is greater than a length of fifth gate pattern 326a; and a length L4 of modified sixth gate pattern 326d is less than a length of sixth gate pattern 326b. Accordingly, in some embodiments, the functional gate structure indicated by modified fifth gate pattern 326c overlaps the first metallization region indicated by first metallization track pattern 232 and overlaps the third metallization region indicated by third metallization track pattern 236. In some embodiments, the length of the non-functional gate structure (e.g., length L4) within a cell region of the eighth circuit cell example, a width of the second active region, and a cell height of the cell region (e.g., H4) along the second direction have relationships as in FIG. 3B.

In some embodiments, the functional gate structure overlaps a metallization region indicated by metallization track pattern 231 sufficient to define via pattern 246. In some embodiments, the functional gate structure further overlaps a metallization region indicated by metallization track pattern 235 to define an overlapped portion having a space defined therein sized for a connection feature between the functional gate structure and the corresponding metallization region (e.g., the space as indicated by via pattern 248). In some embodiments as in FIG. 3D, as the boundary of modified fifth gate pattern 326c is moved farther away from the first active region indicated by first active region pattern 212 by shifting the position of the CPO pattern 334, formation of a via structure based on via pattern 248 is much less susceptible to process variations than the example of FIG. 3C.

Accordingly, as in FIG. 3D, if the functional gate structure indicated by modified fifth gate pattern 326c is to be electrically connected to a conductive track of the metallization layer (e.g., the M0 layer), there are two options in some embodiments, including: connecting the functional gate structure and a conductive track formed based on the first metallization region indicated by first metallization track pattern 231 through a connection feature (e.g., a via structure) indicated by via pattern 246; and connecting the functional gate structure and a conductive track formed based on the third metallization region indicated by third metallization track pattern 235 through a connection feature (e.g., a via structure) indicated by via pattern 248. In some embodiments, compared to the seventh circuit cell example in FIG. 3C, the eighth circuit cell example in FIG. 3D with a shifted CPO pattern (e.g., CPO pattern 332 versus CPO pattern 334) has options and benefits similar to those discussed with reference to FIG. 2B.

The examples in FIGS. 2A-2D and 3A-3D are non-limiting examples. In some embodiments, the CPODE process illustrated in FIGS. 2A-2D and the CPO process illustrated in FIGS. 3A-3D are combinable to define one or more layout patterns of one or more gate structures, regardless of the gate structures being functional or non-functional. For example, in some embodiments, sixth gate pattern 326b and/or modified sixth gate pattern 326d are usable as CPODE patterns.

In some embodiments, the examples in FIGS. 2B, 2D, 3B, and 3D are applicable in various types of circuit cells with different cell heights in order to achieve the improvements and benefits discussed above.

In some embodiments, a semiconductor structure in view of the examples in FIGS. 2B, 2D, 3B, and 3D include a first active region (e.g., indicated by first active region pattern 212) and a second active region (e.g., indicated by second active region pattern 214) extending along a first direction, an isolation region (e.g., indicated by blank region 216) between and adjoining the first active region and the second active region, a functional gate structure (e.g., indicated by modified third gate pattern 226c or modified fifth gate pattern 326c) extending along a second direction and overlapping the first active region, a non-functional gate structure (e.g., indicated by modified fourth gate pattern 226d or modified sixth gate pattern 326c) aligned with the functional gate structure along the second direction and overlapping the second active region, and a metallization layer over the functional gate structure and the non-functional gate structure. In some embodiments, the metallization layer defines a first metallization region (e.g., indicated by metallization track pattern 232 or metallization track pattern 231) extending along the first direction over the first active region, a second metallization region (e.g., indicated by metallization track pattern 234 or metallization track pattern 233) extending along the first direction over the second active region, and one or two middle metallization regions (e.g., indicated by metallization track pattern 236, or metallization track patterns 235 and 237) extending along the first direction and between the first metallization region and the second metallization region. In some embodiments, the functional gate structure overlaps the first metallization region and overlaps one of the one or two middle metallization regions to define an overlapped portion of the one of the one or two middle metallization regions. In some embodiments, the overlapped portion of the one of the one or two middle metallization regions has a space defined therein sized for a connection feature (e.g., indicated by via pattern 244 or via pattern 248) between the functional gate structure and the one of the one or two middle metallization regions.

In some embodiments, a distance between the overlapped portion and the first active region is less than a distance between the overlapped portion and the second active region. In some embodiments, the non-functional gate structure is a first dielectric gate structure adjoining the functional gate structure (e.g., based on a CPODE process), or the non-functional gate structure is a second dielectric gate structure or a conductive gate structure spaced apart from the functional gate structure (e.g., based on a CPO process).

In some embodiments, the one or two middle metallization regions include a third metallization region between the first metallization region and the second metallization region. In some embodiments, a width of the third metallization region is 1.2 to 2 times a width of the first metallization region; or the width of the third metallization region is 1.2 to 2 times a width of the second metallization region. In some embodiments, the one or two middle metallization regions further include a fourth metallization region between the third metallization region and the second metallization region.

In some embodiments, a semiconductor structure in view of the examples in FIGS. 2B, 2D, 3B, and 3D include a first active region (e.g., indicated by first active region pattern 212) and a second active region (e.g., indicated by second active region pattern 214) extending along a first direction, an isolation region (e.g., indicated by blank region 216) between and adjoining the first active region and the second active region, a functional gate structure (e.g., indicated by modified third gate pattern 226c or modified fifth gate pattern 326c) extending along a second direction and overlapping the first active region, and a non-functional gate structure (e.g., indicated by modified fourth gate pattern 226d or modified sixth gate pattern 326c) aligned with the functional gate structure along the second direction and overlapping the second active region. In some embodiments, the semiconductor structure includes a first conductive track (e.g., formed based on a metallization region indicated by metallization track pattern 236 or metallization track pattern 235) of a metallization layer extending along the first direction, overlapping the functional gate structure, and overlapping the isolation region. In some embodiments, the semiconductor structure further includes a connection feature (e.g., a via structures formed based on via pattern 244 or via pattern 248) connecting the functional gate structure and the first conductive track.

In some embodiments, the semiconductor structure includes one or more channel structures within the first active region, where the one or more channel structures are under or surrounded by the functional gate structure. In some embodiments, the semiconductor structure includes a first drain/source structure within the first active region and on a first side of the functional gate structure, and a second drain/source structure within the first active region and on a second side of the functional gate structure. In some embodiments, a combination of the functional gate structure, the one or more channel structures, the first drain/source structure, and the second drain/source structure correspond to a planar FET, a FinFET, a nanosheet FET, a nanowire FET, or a CFET.

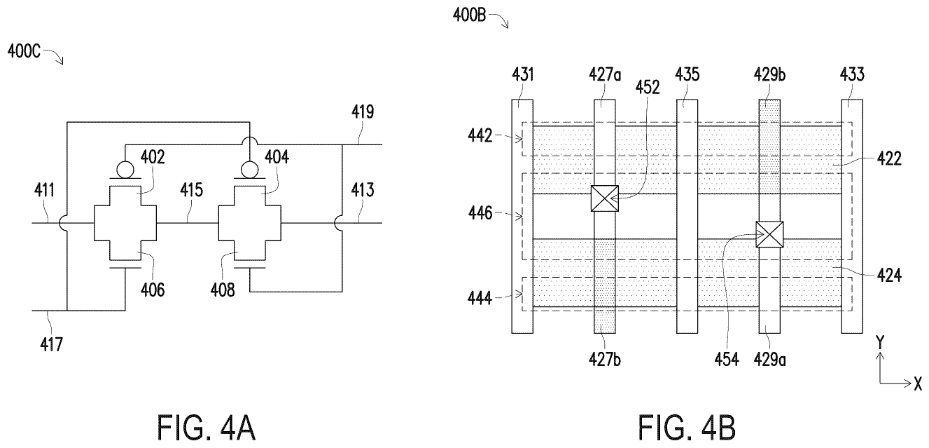

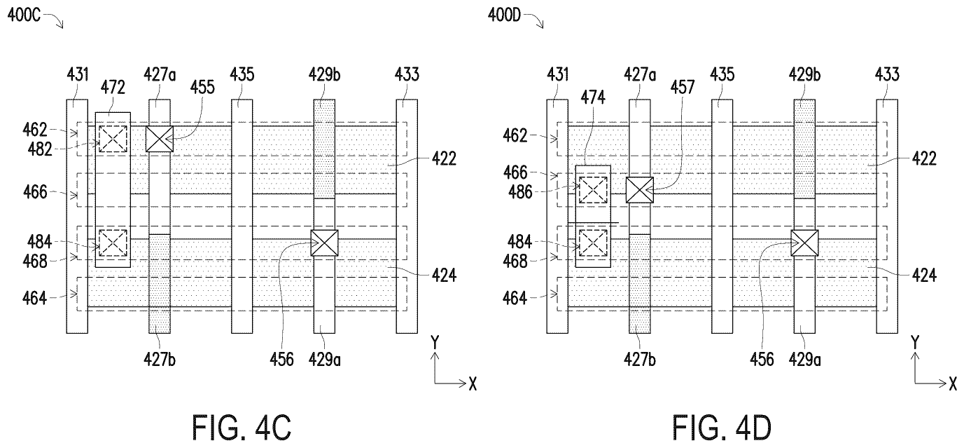

FIGS. 4A-8D include various examples of a semiconductor structure based on shortened CPODE patterns, shifted CPO patterns, or a combination thereof, similar to FIGS. 2B, 2D, 3B, and 3D.

FIG. 4A is a circuit diagram 400A of two transmission gates operable based on complementary control signals, in accordance with some embodiments. The circuit diagram 400A includes two p-type transistors 402 and 404 and two n-type transistors 406 and 408. A first source/drain terminal of p-type transistor 402 and a first source/drain terminal of n-type transistor 406 are electrically coupled to a signal path 411. A first source/drain terminal of p-type transistor 404 and a first source/drain terminal of n-type transistor 408 are electrically coupled to a signal path 413. A second source/drain terminal of p-type transistor 402, a second source/drain terminal of p-type transistor 404, a second source/drain terminal of n-type transistor 406, and a second source/drain terminal of n-type transistor 408 are electrically coupled to a signal path 415. A gate terminal of n-type transistor 406 and a gate terminal of p-type transistor 404 are electrically coupled to a control path 417. A gate terminal of n-type transistor 408 and a gate terminal of p-type transistor 402 are electrically coupled to a control path 419. In some embodiments, the combination of p-type transistor 402 and n-type transistor 406 forms a transmission gate; and the combination of p-type transistor 404 and n-type transistor 408 forms another transmission gate. In some embodiments, control path 417 and control path 419 are configured to carry two complementary control signals.

FIG. 4B is a layout diagram 400B of various layout patterns corresponding to a portion of a circuit cell including two transmission gates operable based on complementary control signals (e.g., the example of circuit diagram 400A in FIG. 4A), in accordance with some embodiments. In some embodiments, the circuit cell in FIG. 4B is a portion of a semiconductor device, such as the semiconductor device 100 in FIG. 1.

Layout diagram 400B includes a first active region pattern 422 indicative of a first active region of the semiconductor device extending along a first direction (e.g., the X direction); and a second active region pattern 424 indicative of a second active region of the semiconductor device extending along the first direction (e.g., the X direction). Layout diagram 400B also includes a first gate pattern 431, a second gate pattern 433, a third gate pattern 435, a first functional gate pattern 427a, a first non-functional gate pattern 427b, a second functional gate pattern 429a, and a second non-functional gate pattern 429b. First functional gate pattern 427a and first non-functional gate pattern 427b are aligned with each other and between first gate pattern 431 and third gate pattern 435. Second functional gate pattern 429a and second non-functional gate pattern 429b are aligned with each other and between second gate pattern 433 and third gate pattern 435.

In some embodiments, first gate pattern 431 and second gate pattern 433 are indicative of two non-functional gate structures extending along a second direction (e.g., the Y direction). In some embodiments, first gate pattern 431 and second gate pattern 433 denote two cell boundaries and correspond to no physical gate structures. First functional gate pattern 427a is indicative of a first functional gate structure extending along the second direction (e.g., the Y direction) and overlapping the first active region. Second functional gate pattern 429a is indicative of a second functional gate structure extending along the second direction (e.g., the Y direction) and overlapping the second active region. First non-functional gate pattern 427b is indicative of a first non-functional gate structure extending along the second direction (e.g., the Y direction) and overlapping the second active region. Second non-functional gate pattern 429b is indicative of a second non-functional gate structure extending along the second direction (e.g., the Y direction) and overlapping the first active region. In some embodiments, third gate pattern 435 is indicative of a third functional gate structure extending along the second direction (e.g., the Y direction) and overlapping the first active region and the second active region. As in FIG. 4B as a non-limiting example, the non-functional gate structures indicated by non-functional gate pattern 427b and non-functional gate pattern 429b are formed based on a CPODE process, where, in some embodiments, non-functional gate pattern 427b and non-functional gate pattern 429b are also referred to as CPODE patterns.

In some embodiments, the first functional gate structure and the first active region define a first p-type transistor that corresponds to p-type transistor 402 in FIG. 4A; and the third functional gate structure and the first active region define a second p-type transistor that corresponds to p-type transistor 404 in FIG. 4A. In some embodiments, the third functional gate structure and the second active region define a first n-type transistor that corresponds to n-type transistor 406 in FIG. 4A; and the second functional gate structure and the second active region define a second n-type transistor that corresponds to n-type transistor 408 in FIG. 4A.

In some embodiments, the circuit cell as in FIG. 4B includes a metallization layer (e.g., an M0 layer) over the functional gate structures and the non-functional gate structures. As a non-limiting example, layout diagram 400B includes the circuit cell that has three metallization regions in the M0 layer. Layout diagram 400B includes a first metallization track pattern 442, a second metallization track pattern 444, and a third metallization track pattern 446 corresponding to three metallization regions defined in the metallization layer. For example, first metallization track pattern 442 is indicative of a first metallization region extending along the first direction (e.g., the X direction) over the first active region; second metallization track pattern 444 is indicative of a second metallization region extending along the first direction (e.g., the X direction) over the second active region, and third metallization track pattern 446 is indicative of a third metallization region extending along the first direction (e.g., the X direction) and between the first metallization region and the second metallization region.

In some embodiments, the gate terminals of p-type transistor 404 and n-type transistor 406 in FIG. 4A correspond to the third functional gate structure indicated by third gate pattern 435 in FIG. 4B and are electrically coupled based on the shared third functional gate structure. In some embodiments, the gate terminal of p-type transistor 402 corresponds to the first functional gate structure indicated by first functional gate pattern 427a in FIG. 4B and is electrically coupled to a conductive track formed based on a metallization region indicated by the third metallization track pattern 446 through a connection feature (e.g., a via structure) indicated by a via pattern 452. In some embodiments, the gate terminal of n-type transistor 408 corresponds to the second functional gate structure indicated by second functional gate pattern 429a in FIG. 4B and is also electrically coupled to the conductive track through a connection feature (e.g., a via structure) indicated by a via pattern 454, and hence electrically coupled to the gate terminal of p-type transistor 402.

FIG. 4B is an example of implementing the example of FIG. 4A based on the example in FIG. 2B. In some embodiments, the lengths of the non-functional gate structures, the widths of the active regions, and a cell height of the circuit cell along the second direction in FIG. 4B have relationships similar to those in FIG. 2B. In some embodiments, the widths of the third metallization regions of the M0 layer along the second direction in FIG. 4B have relationships similar to those in FIG. 2B.

In some embodiments, by limiting the length of first non-functional gate pattern 427b and second non-functional gate pattern 429b in a manner as discussed in FIG. 2B, together with a wider third metallization track pattern 446 than first metallization track pattern 442 or second metallization track pattern 444, the gate terminals of p-type transistor 402 and n-type transistor 408 are electrically coupled without using any routing resources corresponding to first metallization track pattern 442, second metallization track pattern 446, and any other metallization layer above the M0 layer. Accordingly, in some embodiments, the implementation of the circuit of FIG. 4A based on the example in FIG. 4B with shortened CPODE patterns (e.g., in view of the example of FIG. 2B) frees up more routing resources and reduces resistance of conductive paths compared to another implementation of the circuit of FIG. 4A without shortened CPODE patterns (e.g., in view of the example of FIG. 2A).

FIG. 4C is a layout diagram 400C of various layout patterns corresponding to a portion of a circuit cell including two transmission gates operable based on complementary control signals (e.g., the circuit example in the circuit diagram 400A in FIG. 4A), in accordance with some embodiments. The circuit cell in FIG. 4C is a variation of the circuit cell in FIG. 4B. Therefore, components depicted in FIG. 4C that are the same or similar to those in FIG. 4B are given the same reference numbers, and detailed description thereof is simplified or omitted.

Compared with layout diagram 400B, layout diagram 400C includes a circuit cell that has four metallization regions in an M0 layer, including four metallization track patterns 462, 464, 466, and 468 indicative of four respective metallization regions extending along the first direction (e.g., the X direction). In some embodiments, the widths of the metallization regions indicated by the metallization track patterns 462, 464, 466, and 468 are substantially the same (e.g., having a variation within 10% of a nominal width).

In some embodiments, the gate terminal of p-type transistor 402 corresponds to the first functional gate structure indicated by first functional gate pattern 427a and is electrically coupled to a first conductive track formed based on a metallization region indicated by metallization track pattern 462 through a connection feature (e.g., a via structure) indicated by a via pattern 455. In some embodiments, the gate terminal of n-type transistor 408 corresponds to the second functional gate structure indicated by second functional gate pattern 429a and is electrically coupled to a second conductive track formed based on a metallization region indicated by metallization track pattern 468 through a connection feature (e.g., a via structure) indicated by a via pattern 456. In some embodiments, as in FIG. 4C, the first conductive track and the second conductive track are electrically coupled together through a third conductive track (indicated by a metallization track pattern 472) at a metallization layer above the M0 layer and along the second direction (e.g., the Y direction), a via structure (indicated by a via pattern 482) connecting the first conductive track (based on the metallization region indicated by metallization track patterns 462) and the third conductive track, and a via structure (indicated by a via pattern 484) connecting the second conductive track (based on the metallization region indicated by metallization track patterns 468) and the third conductive track.

FIG. 4D is a layout diagram 400D of various layout patterns corresponding to a portion of a circuit cell including two transmission gates operable based on complementary control signals (e.g., the circuit example of the circuit diagram 400A in FIG. 4A), in accordance with some embodiments. The circuit cell in FIG. 4D is a variation of the circuit cell in FIG. 4C. Therefore, components depicted in FIG. 4D that are the same or similar to those in FIG. 4B and FIG. 4C are given the same reference numbers, and detailed description thereof is simplified or omitted.

Similar to layout diagram 400C, layout diagram 400D also includes a circuit cell that has four metallization regions in an M0 layer, including four metallization track patterns 462, 464, 466, and 468 indicative of four respective metallization regions extending along the first direction (e.g., the X direction). Compared with layout diagram 400C, in some embodiments, the gate terminal of p-type transistor 402 corresponds to the first functional gate structure indicated by first functional gate pattern 427a is electrically coupled to a fourth conductive track formed based on a metallization region indicated by metallization track pattern 466 through a connection feature (e.g., a via structure) indicated by a via pattern 457. In some embodiments, the gate terminal of n-type transistor 408 corresponds to the second functional gate structure indicated by second functional gate pattern 429a is electrically coupled to a second conductive track formed based on a metallization region indicated by metallization track pattern 468 through a connection feature (e.g., a via structure) indicated by a via pattern 456. In some embodiments, as in FIG. 4D, the fourth conductive track and the second conductive track are electrically coupled together through a fifth conductive track (indicated by a metallization track pattern 474) at a metallization layer above the M0 layer and along the first direction (e.g., the Y direction), a via structure (indicated by a via pattern 486) connecting the fifth conductive track (based on the metallization region indicated by metallization track patterns 466) and the fourth conductive track, and a via structure (indicated by a via pattern 484) connecting the second conductive track (based on the metallization region indicated by metallization track patterns 468) and the fifth conductive track.

In some embodiments, FIGS. 4C and 4D are two examples of implementing the example of FIG. 4A based on the example in FIG. 2D. In some embodiments, the lengths of the non-functional gate structures, the widths of the active regions, and a cell height of the circuit cell along the second direction in FIGS. 4C and 4D have relationships similar to those in FIG. 2D. In some embodiments, the widths of the third metallization regions of the M0 layer along the second direction in FIGS. 4C and 4D have relationships similar to those in FIG. 2D.

In some embodiments, by limiting the length of first non-functional gate pattern 429a and second non-functional gate pattern 429b and with four metallization regions at an M0 layer of a circuit cell in a manner as discussed in FIG. 2D, various routing options for electrically connecting the gate terminals of p-type transistor 402 and n-type transistor 408 become available. Accordingly, in some embodiments, the implementation of the circuit of FIG. 4A based on the examples in FIGS. 4C and 4D with shortened CPODE patterns (e.g., in view of the example of FIG. 2D) adds more routing options and thus increases routing flexibility compared to another implementation of the circuit of FIG. 4A without shortened CPODE patterns (e.g., in view of the example of FIG. 2C).

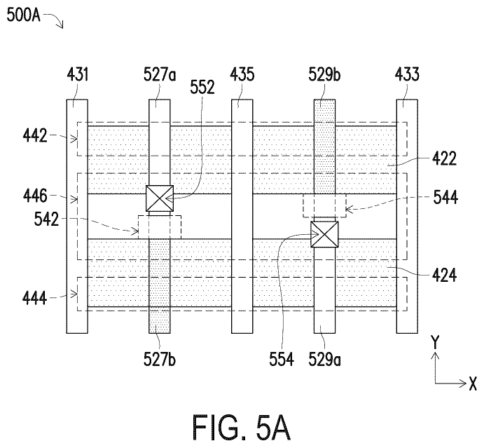

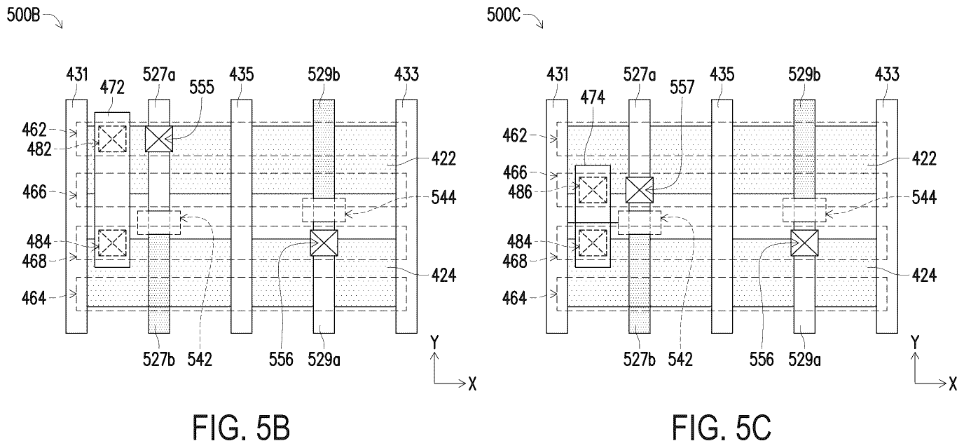

FIG. 5A is a layout diagram 500A of various layout patterns corresponding to a portion of a circuit cell including two transmission gates operable based on complementary control signals (e.g., the circuit example of the circuit diagram 400A in FIG. 4A), in accordance with some embodiments. The circuit cell in FIG. 5A is a variation of the circuit cell in FIG. 4B. Therefore, components depicted in FIG. 5A that are the same or similar to those in FIG. 4B are given the same reference numbers, and detailed description thereof is simplified or omitted.

Compared with layout diagram 400B in FIG. 4B, layout diagram 500A includes a third functional gate pattern 527a, a third non-functional gate pattern 527b, a fourth functional gate pattern 529a, and a fourth non-functional gate pattern 529b. Third functional gate pattern 527a is indicative of a fourth functional gate structure extending along the second direction (e.g., the Y direction) and overlapping the first active region. Fourth functional gate pattern 529a is indicative of a fifth functional gate structure extending along the second direction (e.g., the Y direction) and overlapping the second active region. Third non-functional gate pattern 527b is indicative of a fourth non-functional gate structure extending along the second direction (e.g., the Y direction) and overlapping the second active region. Fourth non-functional gate pattern 529b is indicative of a fifth non-functional gate structure extending along the second direction (e.g., the Y direction) and overlapping the first active region. As in FIG. 5A as a non-limiting example, the fourth functional gate structure indicated by third functional gate pattern 527a and the fourth non-functional gate structure indicated by third non-functional gate pattern 527b are formed based on a CPO process based on a CPO pattern 542; and the fifth functional gate structure indicated by fourth functional gate pattern 529a and the fifth non-functional gate structure indicated by fourth non-functional gate pattern 529b are formed based on a CPO process based on a CPO pattern 544.

In some embodiments, the fourth functional gate structure and the first active region define a first p-type transistor that corresponds to p-type transistor 402 in FIG. 4A; and the third functional gate structure and the first active region define a second p-type transistor that corresponds to p-type transistor 404 in FIG. 4A. In some embodiments, the third functional gate structure and the second active region define a first n-type transistor that corresponds to n-type transistor 406 in FIG. 4A; and the fifth functional gate structure and the second active region define a second n-type transistor that corresponds to n-type transistor 408 in FIG. 4A.

In some embodiments, the gate terminal of p-type transistor 402 corresponds to the fourth functional gate structure indicated by third functional gate pattern 427a in FIG. 5A and is electrically coupled to a conductive track formed based on a metallization region indicated by the third metallization track pattern 446 through a connection feature (e.g., a via structure) indicated by a via pattern 552. In some embodiments, the gate terminal of n-type transistor 408 corresponds to the fifth functional gate structure indicated by fourth functional gate pattern 529a in FIG. 5A and is also electrically coupled to the conductive track through a connection feature (e.g., a via structure) indicated by a via pattern 554, and hence electrically coupled to the gate terminal of p-type transistor 402.

In some embodiments, FIG. 5A is an example of implementing the example of FIG. 4A based on the example in FIG. 3B. In some embodiments, the lengths of the non-functional gate structures, the widths of the active regions, and a cell height of the circuit cell along the second direction in FIG. 5A have relationships similar to those in FIG. 3B. In some embodiments, the widths of the third metallization regions of the M0 layer along the second direction in FIG. 5A have relationships similar to those in FIG. 3B.

In some embodiments, by shifting the CPO patterns 542 and 544 to extend the lengths of third functional gate pattern 527a and fourth functional gate pattern 529a in a manner as discussed in FIG. 3B, together with a wider third metallization track pattern 446 than first metallization track pattern 442 or second metallization track pattern 444, the gate terminals of p-type transistor 402 and n-type transistor 408 are electrically coupled without using any routing resources corresponding to first metallization track pattern 442, second metallization track pattern 446, and any other metallization layer above the M0 layer. Accordingly, in some embodiments, the implementation of the circuit of FIG. 4A based on the example in FIG. 5A with shifted CPO patterns (e.g., in view of the example of FIG. 3B) frees up more routing resources and reduces resistance of conductive paths compared to another implementation of the circuit of FIG. 4A with CPO patterns in the middle between first active region pattern 422 and second active region pattern 424 (e.g., in view of the example of FIG. 3A).

FIG. 5B is a layout diagram 500B of various layout patterns corresponding to a portion of a circuit cell including two transmission gates operable based on complementary control signals (e.g., the circuit example in the circuit diagram 400A in FIG. 4A), in accordance with some embodiments. The circuit cell in FIG. 5B is a variation of the circuit cell in FIG. 5A. Therefore, components depicted in FIG. 5B that are the same or similar to those in FIG. 5A are given the same reference numbers, and detailed description thereof is simplified or omitted.

Compared with layout diagram 500A, layout diagram 500B includes a circuit cell that has four metallization regions in an M0 layer, including four metallization track patterns 462, 464, 466, and 468 indicative of four respective metallization regions extending along the first direction (e.g., the X direction). In some embodiments, the widths of the metallization regions indicated by the metallization track patterns 462, 464, 466, and 468 are substantially the same (e.g., having a variation within 10% of a nominal width).

In some embodiments, the gate terminal of p-type transistor 402 corresponds to the fourth functional gate structure indicated by third functional gate pattern 527a and is electrically coupled to a first conductive track formed based on a metallization region indicated by metallization track pattern 462 through a connection feature (e.g., a via structure) indicated by a via pattern 555. In some embodiments, the gate terminal of n-type transistor 408 corresponds to the fifth functional gate structure indicated by fourth functional gate pattern 529a and is electrically coupled to a second conductive track formed within a metallization region indicated by metallization track pattern 468 through a connection feature (e.g., a via structure) indicated by a via pattern 556. In some embodiments, as in FIG. 5B, the first conductive track and the second conductive track are electrically coupled together through a third conductive track (indicated by a metallization track pattern 472) at a metallization layer above the M0 layer and along the second direction (e.g., the Y direction), a via structure (indicated by a via pattern 482) connecting the first conductive track (based on the metallization region indicated by metallization track patterns 462) and the third conductive track, and a via structure (indicated by a via pattern 484) connecting the second conductive track (based on the metallization region indicated by metallization track patterns 468) and the third conductive track.

FIG. 5C is a layout diagram 500C of various layout patterns corresponding to a portion of a circuit cell including two transmission gates operable based on complementary control signals (e.g., the circuit example in the circuit diagram 400A in FIG. 4A), in accordance with some embodiments. The circuit cell in FIG. 5C is a variation of the circuit cell in FIG. 5B. Therefore, components depicted in FIG. 5C that are the same or similar to those in FIG. 5A and FIG. 5B are given the same reference numbers, and detailed description thereof is simplified or omitted.

Similar to layout diagram 500B, layout diagram 500C also includes a circuit cell that has four metallization regions in an M0 layer, including four metallization track patterns 462, 464, 466, and 468 indicative of four respective metallization regions extending along the first direction (e.g., the X direction). Compared with layout diagram 500B, in some embodiments, the gate terminal of p-type transistor 402 corresponds to the fourth functional gate structure indicated by third functional gate pattern 527a is electrically coupled to a fourth conductive track formed based on a metallization region indicated by metallization track pattern 468 through a connection feature (e.g., a via structure) indicated by a via pattern 557. In some embodiments, the gate terminal of n-type transistor 408 corresponds to the fifth functional gate structure indicated by fourth functional gate pattern 529a is electrically coupled to a second conductive track formed based on a metallization region indicated by metallization track pattern 468 through a connection feature (e.g., a via structure) indicated by a via pattern 556. In some embodiments, as in FIG. 5C, the fourth conductive track and the second conductive track are electrically coupled together through a fifth conductive track (indicated by a metallization track pattern 474) at a metallization layer above the M0 layer and along the second direction, a via structure (indicated by a via pattern 486) connecting the fifth conductive track (based on the metallization region indicated by metallization track patterns 466) and the fourth conductive track, and a via structure (indicated by a via pattern 484) connecting the second conductive track (based on the metallization region indicated by metallization track patterns 468) and the third conductive track.

In some embodiments, FIGS. 5B and 5C are two examples of implementing the example of FIG. 4A based on the example in FIG. 3D. In some embodiments, the lengths of the non-functional gate structures, the widths of the active regions, and a cell height of the circuit cell along the second direction in FIGS. 5B and 5C have relationships similar to those in FIG. 3D. In some embodiments, the widths of the third metallization regions of the M0 layer along the second direction in FIGS. 5B and 5C have relationships similar to those in FIG. 3D.

In some embodiments, by arranging the CPO patterns 542 and 544 at shifted positions in a manner as discussed in FIG. 3D, various routing options for electrically connecting the gate terminals of p-type transistor 402 and n-type transistor 408 become available. Accordingly, in some embodiments, the implementation of the circuit of FIG. 4A based on the examples in FIGS. 5B and 5C with shifted CPO patterns (e.g., in view of the example of FIG. 3D) adds more routing options and thus increases routing flexibility compared to another implementation of the circuit of FIG. 4A without shifted CPO patterns (e.g., in view of the example of FIG. 3A).

The examples in FIGS. 4A-4D and 5A-5C are non-limiting examples. In some embodiments, there is no restriction with respect to whether a gate pattern defined based on a shortened CPODE pattern corresponds to a functional gate structure or a non-functional gate structure. In some embodiments, a gate pattern is subject to be converted to two shortened CPODE patterns and correspond to non-functional gate structures. Also, in some embodiments, the CPODE process and the CPO process are combinable to define one or more layout pattern of one or more gate structures, regardless of the gate structures being functional or non-functional.

In some embodiments, a semiconductor structure in view of the examples in FIGS. 2B, 2D, 3B, and 3D, as well as FIGS. 4A-5C include a first active region (e.g., indicated by first active region pattern 422) and a second active region (e.g., indicated by second active region pattern 424) extending along a first direction, an isolation region between and adjoining the first active region and the second active region, a first functional gate structure (e.g., indicated by first functional gate pattern 427a or third functional gate pattern 527a) extending along a second direction and overlapping the first active region, a first non-functional gate structure (e.g., indicated by first non-functional gate pattern 427b or third non-functional gate pattern 527b) aligned with the first functional gate structure along the second direction and overlapping the second active region, a second functional gate structure (e.g., indicated by second functional gate pattern 429a or fourth functional gate pattern 529a) extending along the second direction and overlapping the second active region, and a second non-functional gate structure (e.g., indicated by second non-functional gate pattern 429b or fourth non-functional gate pattern 529b) aligned with the second functional gate structure along the second direction and overlapping the first active region. In some embodiments, the semiconductor structure further includes a first conductive track (e.g., indicated by metallization track pattern 446, metallization track pattern 462, or metallization track pattern 466), a second conductive track (e.g., indicated by metallization track pattern 468), or both, of a metallization layer extending along the first direction and overlapping the isolation region. In some embodiments, the semiconductor structure further includes a first connection feature (e.g., indicated by via pattern 452, via pattern 455, via pattern 552, or via pattern 555) connecting the first functional gate structure and the first conductive track, and a second connection feature (e.g., indicated by via pattern 454, via pattern 456, via pattern 554, or via pattern 556) connecting the second functional gate structure and the first conductive track, or connecting the second functional gate structure and the second conductive track.

In some embodiments, a distance between the first connection feature and the first active region is less than a distance between the first connection feature and the second active region. In some embodiments, a distance between the second connection feature and the second active region is less than a distance between the second connection feature and the first active region.

In some embodiments, the semiconductor structure further includes a third conductive track (e.g., indicated by metallization track pattern 442 or metallization track pattern 462). In some embodiments, the third conductive track overlaps the first active region and is farther away from the second active region than the first conductive track (e.g., indicated by metallization track pattern 446 or metallization track pattern 466). In some embodiments, the second connection feature connects the second functional gate structure and the first conductive track, and a width of the first conductive track is 1.2 to 2 times a width of the third conductive track.

In some embodiments, the second connection feature connects the second functional gate structure and the second conductive track. In some embodiments, the semiconductor structure further includes a third conductive track (e.g., indicated by metallization track pattern 472 or metallization track pattern 474) of another metallization layer extending along the second direction, a third connection feature (e.g., indicated by via pattern 482 or via pattern 486) connecting the first conductive track and the third conductive track, and a fourth connection feature (e.g., indicated by via pattern 484) connecting the second conductive track and the third conductive track.

In some embodiments, the first non-functional gate structure is a first dielectric gate structure adjoining the first functional gate structure (e.g., based on a CPODE process), or the first non-functional gate structure is a second dielectric gate structure or a first conductive gate structure spaced apart from the first functional gate structure (e.g., based on a CPO process). In some embodiments, the second non-functional gate structure is a third dielectric gate structure adjoining the second functional gate structure (e.g., based on a CPODE process), or the second non-functional gate structure is a fourth dielectric gate structure or a second conductive gate structure spaced apart from the second functional gate structure (e.g., based on a CPO process).

In some embodiments, the semiconductor structure includes one or more channel structures within the first active region, where the one or more channel structures are under or surrounded by the first functional gate structure. In some embodiments, the semiconductor structure includes a first drain/source structure within the first active region and on a first side of the first functional gate structure, and a second drain/source structure within the first active region and on a second side of the first functional gate structure. In some embodiments, a combination of the first functional gate structure, the one or more channel structures, the first drain/source structure, and the second drain/source structure correspond to a planar FET, a FinFET, a nanosheet FET, a nanowire FET, or a CFET.

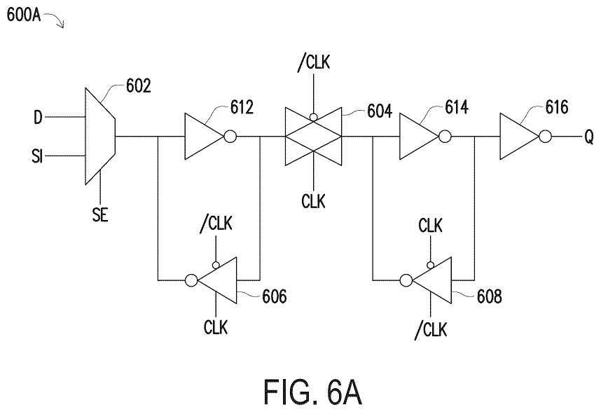

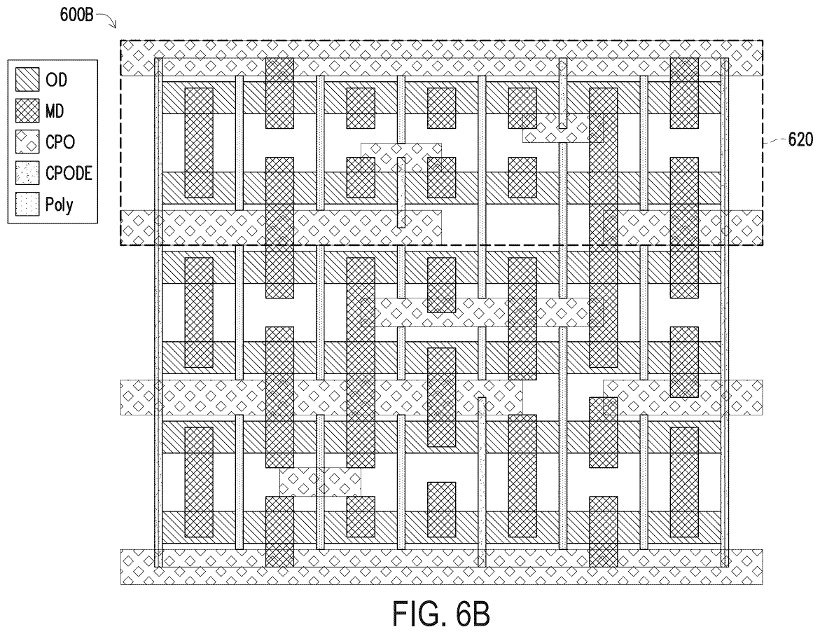

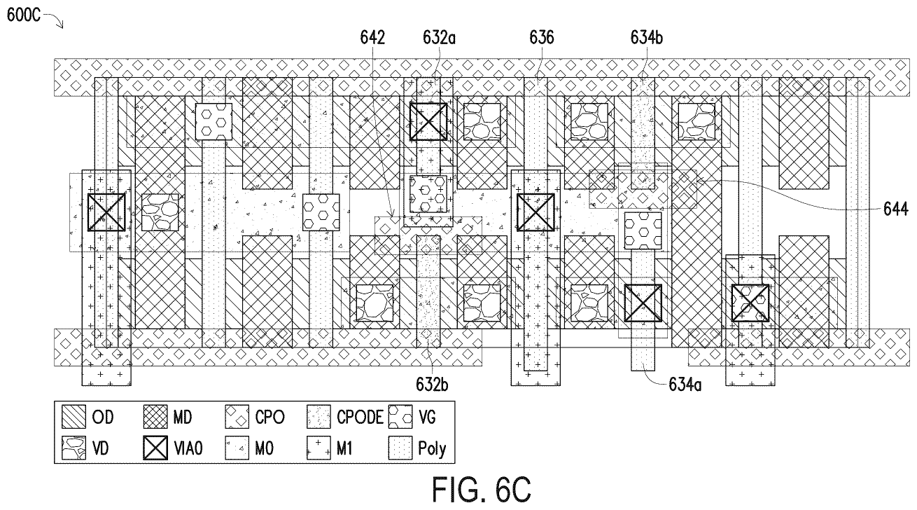

FIG. 6A is a circuit diagram 600A of a flip-flop circuit example, in accordance with some embodiments. In some embodiments, circuit diagram 600A includes components of the flip-flop circuit example as a simplified, non-limiting example. In FIG. 6A, the flip-flop circuit includes a 2:1 multiplexer circuit (MUX) 602, a transmission gate 604, two clocked inverters 606 and 608, and three inverters 612, 614, and 616.

In FIG. 6A, an output terminal of MUX 602, an output terminal of clocked inverter 606, and an input terminal of inverter 612 are electrically coupled together. An output terminal of inverter 612 and an input terminal of clocked inverter 606 are electrically coupled to a first terminal of transmission gate 604. An output terminal of clocked inverter 608 and an input terminal of inverter 614 are electrically coupled to a second terminal of transmission gate 604. An output terminal of inverter 614 and an input terminal of clocked inverter 608 are electrically coupled to an input terminal of inverter 616. In some embodiments, MUX 602 includes a first input terminal configured to receive a first input signal (labeled “D”), a second input terminal configured to receive a second input signal (labeled “SI”), and a selection terminal configured to receive a selection signal (labeled “SE”). An output terminal of the inverter 616 is configured to output an output signal (labeled “Q”) of the flip-flop circuit.

In some embodiments, the operations of various components of the flip-flop circuit are based on two complementary clock signals (labeled “CLK” and “/CLK”). For example, clocked inverter 606 is configured to function as an inverter when clock signal CLK is at a high voltage level (also referred to as “HIGH”) and clock signal/CLK is at a low voltage level (also referred to as “LOW”); and to function as an open-circuit when clock signal CLK is LOW and clock signal/CLK is HIGH. In contrast, clocked inverter 608 is configured to function as an inverter when clock signal CLK is LOW and clock signal/CLK is HIGH; and to function as an open-circuit when clock signal CLK is HIGH and clock signal/CLK is LOW. Also, transmission gate 604 is configured to function as a short-circuit when clock signal CLK is HIGH and clock signal/CLK is LOW; and to function as an open-circuit when clock signal CLK is LOW and clock signal/CLK is HIGH. In some embodiments, the control signal paths for clock signals CLK and/CLK and corresponding transistors controlled thereby may include cross-coupling gate terminals of transistors of different types.

FIG. 6B is a layout diagram 600B of various layout patterns corresponding to a portion of a circuit cell of the flip-flop circuit example of FIG. 6A, in accordance with some embodiments. In FIG. 6B, layout diagram 600A includes layout patterns for forming active regions (labeled as “OD”), forming conductive structures connected to source/drain structures (labeled as “MD”), defining CPO patterns for a CPO process (labeled as “CPO”), defining CPODE patterns for a CPODE process (labeled as “CPODE”), and defining positions of gate structures (labeled as “Poly”). FIG. 6B identifies a portion 620 of layout diagram 600B that will be further described in connection with FIG. 6C. In some embodiments, portion 620 corresponds to formation of the components of transmission gate 604, clocked inverter 608, and inverters 614 and 616.

FIG. 6C is a layout diagram 600C of various layout patterns corresponding to a portion of the flip-flop circuit example of FIG. 6A that corresponds to the portion 620 identified in FIG. 6B, in accordance with some embodiments. As in FIG. 6C, layout diagram 600C includes layout patterns for forming active regions (labeled as “OD”), forming conductive structures connected to source/drain structures (labeled as “MD”), defining CPO patterns for a CPO process (labeled as “CPO”), defining CPODE patterns for a CPODE process (labeled as “CPODE”), and defining positions of gate structures (labeled as “Poly”). In FIG. 6B, layout diagram 600B further includes layout patterns for forming via structures (labeled as “VG” and “VIA0”) and forming conductive tracks (labeled as “M0” and “M1”).

In FIGS. 6A and 6C, the circuit cell includes components that correspond to clocked inverter 608 and transmission gate 604 with various transistors operable based on complementary control signals. In some embodiments, layout pattern 632a is indicative of forming a gate terminal of a p-type transistor of clocked inverter 608; layout pattern 636 is indicative of forming a gate terminal of a p-type transistor of transmission gate 604 and an n-type transistor of clocked inverter 608; and layout pattern 634a is indicative of forming a gate terminal of an n-type transistor of transmission gate 604. In some embodiments, the size of the layout pattern 632a and the layout pattern 634a are determined based on a CPODE pattern 632b, a CPO pattern 642, a CPODE pattern 634b, and/or a CPO pattern 644, in a manner similar to the examples in FIGS. 2B, 3B, 4A-4D, and 5A-5C. Accordingly, in some embodiments, the implementation of the flip-flop circuit example of FIG. 6A based on layout diagrams in FIGS. 6B and 6C with shortened CPODE patterns and/or shifted CPO patterns adds more routing options and thus increases routing flexibility compared to another implementation without shortened CPODE patterns and without shifted CPO patterns.

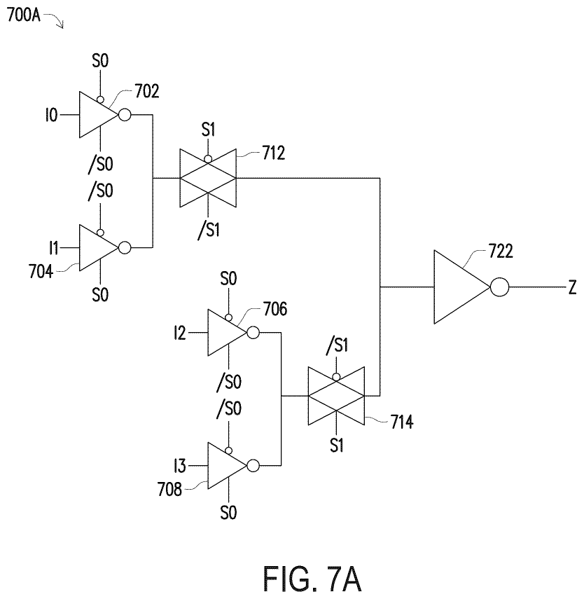

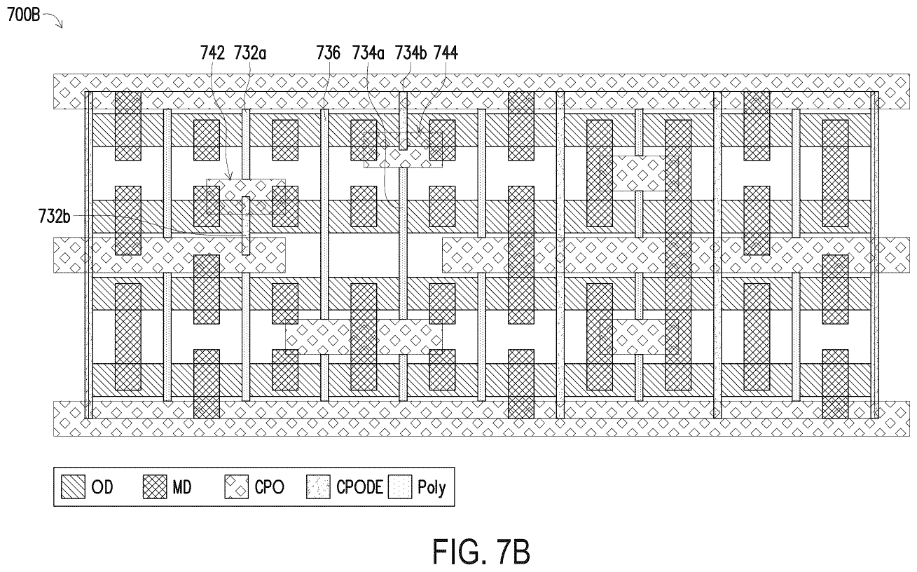

FIG. 7A is a circuit diagram 700A of a 4:1 multiplexer circuit example, in accordance with some embodiments. Circuit diagram 700A includes components of the multiplexer circuit example as a simplified, non-limiting example. In FIG. 7A, the multiplexer circuit includes four clocked inverters 702, 704, 706, and 708, two transmission gates 712 and 714, and an inverter 722.

In FIG. 7A, output terminals of clocked inverters 702 and 704 are electrically coupled to a first terminal of transmission gate 712; and output terminals of clocked inverters 706 and 708 are electrically coupled to a first terminal of transmission gate 714. Also, a second terminal of transmission gate 712 and a second terminal of transmission gate 714 are electrically coupled to an input terminal of inverter 722. Input terminals of clocked inverters 702, 704, 706, and 708 are configured to receive four corresponding input signals (labeled as “I0,” “I1,” “I2,” and “I3,”). An output terminal of inverter 722 is configured to output an output signal (labeled “Z”) of the multiplexer circuit.

In some embodiments, the operations of various components of the multiplexer circuit are based on two sets of complementary selection signals (labeled “S0,” “/S0,” “S1,” and “/S1”). For example, clocked inverters 702 and 706 are configured to function as an inverter responsive to selection signal S0 being LOW and selection signal/S0 being HIGH; and clocked inverters 704 and 708 are configured to function as an inverter responsive to selection signal S0 being HIGH and selection signal/S0 being LOW. Transmission gate 712 is configured to function as a short-circuit in response to selection signal S1 being LOW and selection signal/S1 being HIGH; and to function as an open-circuit in response to selection signal S1 being HIGH and selection signal/S1 being LOW. Also, transmission gate 714 is configured to function as a short-circuit responsive to selection signal S1 being HIGH and selection signal/S1 being LOW; and to function as an open-circuit in response to selection signal S1 being LOW and selection signal/S1 being HIGH. In some embodiments, the control signal paths for selection signals S0 and/S0, or the control signal paths for selection signals S1 and/S1, and corresponding transistors controlled thereby include cross-coupling gate terminals of transistors of different types.

FIG. 7B is a layout diagram 700B of various layout patterns corresponding to a portion of a circuit cell of the 4:1 multiplexer circuit example of FIG. 7A, in accordance with some embodiments. In FIG. 7B, layout diagram 700B includes layout patterns for forming active regions (labeled as “OD”), forming conductive structures connected to source/drain structures (labeled as “MD”), defining CPO patterns for a CPO process (labeled as “CPO”), defining CPODE patterns for a CPODE process (labeled as “CPODE”), and defining positions of gate structures (labeled as “Poly”).

In FIG. 7B, the circuit cell includes components that correspond to two transmission gates operable based on complementary control signals (e.g., transmission gates 712 and 714). In some embodiments, layout pattern 732a is indicative of forming a gate terminal of a p-type transistor of transmission gate 712, layout pattern 734a is indicative of forming a gate terminal of a n-type transistor of transmission gate 714, and layout pattern 736 is indicative of forming a gate terminal of a p-type transistor of transmission gate 714 and a gate terminal of a n-type transistor of transmission gate 712. In some embodiments, the size of the layout pattern 732a and the layout pattern 734a are determined based on a CPODE pattern 732b, a CPO pattern 742, a CPODE pattern 734b, and/or a CPO pattern 744, based on the examples in FIGS. 2B, 3B, 4A-4D, and 5A-5C. Accordingly, in some embodiments, the implementation of the 4:1 multiplexer circuit of FIG. 7A implemented based on FIG. 7B with shortened CPODE patterns and/or shifted CPO patterns adds more routing options and thus increases routing flexibility compared to another implementation without shortened CPODE patterns and without shifted CPO patterns.

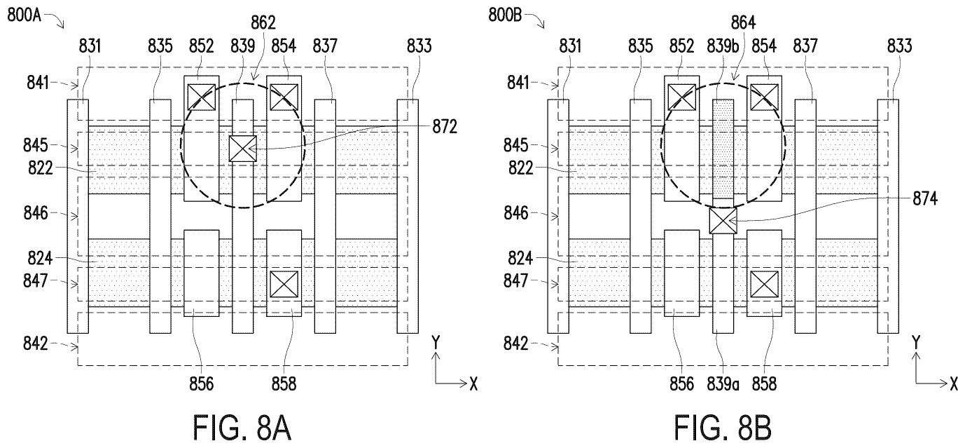

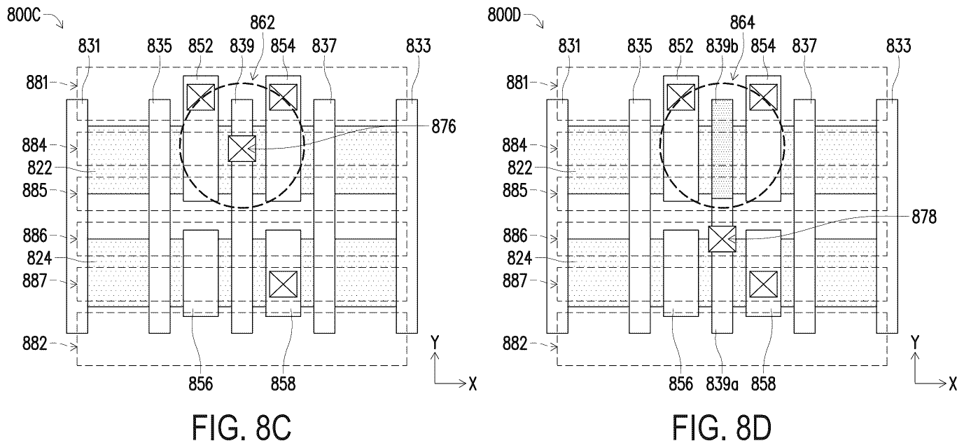

FIG. 8A is a layout diagram 800A of various layout patterns corresponding to a portion of a first circuit cell example of a skewed logic circuit, in accordance with some embodiments. In some embodiments, a skewed logic circuit corresponds to a logic circuit (e.g., a logic gate or a combination of logic gates) having a greater driving power to pull a signal to a supply voltage over another supply voltage at certain stage thereof (e.g., having greater driving power to pull up to VDD, or to pull down to VSS or a ground level). As such, the skewed logic circuit may include a greater number of transistors of a certain type (e.g., p-type transistors for pulling up or n-type transistors for pulling down), and leaving a number of unused gate structures and corresponding source/drain structures (which may be configured as dummy transistors) in a circuit cell.

As a non-limiting example, layout diagram 800A includes active region patterns 822 and 824 indicative of active regions extending along a first direction (e.g., the X direction); gate patterns 831, 833, 835, 837, and 839 indicative of gate structures or one or more cell boundaries; and metallization track patterns 841, 842, 845, 846, and 847 indicative of metallization regions of a metallization layer (e.g., the M0 layer). In some embodiments, the metallization track pattern 841 corresponds to a metallization region for forming a first power rail configured to carry a first supply voltage (e.g., VDD). In some embodiments, the metallization track pattern 842 corresponds to a metallization region for forming a second power rail configured to carry a second supply voltage (e.g., VSS or the ground level).

In FIG. 8A, two contact patterns 852 and 854 overlap the active region indicated by active region pattern 822 on each side of the gate patterns 839 and are indicative of forming corresponding source/drain terminals. Also, two contact patterns 856 and 858 overlap the active region indicated by active region pattern 824 on each side of the gate patterns 839 and are indicative of forming two other corresponding source/drain terminals. In this example, as the metallization region indicated by metallization track pattern 847 is likely reserved for being connected to the source/drain terminal indicated by contact patterns 858, the metallization regions indicated by metallization track patterns 845 and 846 are still available for a via structure to land thereon for connecting the gate structure to M0 (e.g., a via pattern 872 indicative a via structure overlapping the metallization track pattern 845).

In some embodiments, the gate structure indicated by the gate patterns 839 and the source/drain terminals under the contact patterns 852 and 854 form a dummy transistor (as indicated by reference number 862), with the source/drain terminals electrically connected to the first power rail (e.g., indicated by metallization track pattern 841) through two via structures indicated by two via patterns (not labeled). In some embodiments, while the dummy transistor 862 is not logically functional, the dummy transistor 862 still introduces parasitic capacitance between the gate structure and the source/drain terminals (indicated by contact patterns 852 and 854).

FIG. 8B is a layout diagram 800B of various layout patterns corresponding to a portion of a second circuit cell example of a skewed logic circuit, in accordance with some embodiments. The second circuit cell example is a variation of the first circuit cell example. Components in FIG. 8B that are the same or similar to those in FIG. 8A are given the same reference numbers, and detailed description thereof is simplified or omitted.

In FIG. 8B, by converting the gate structure indicated by gate pattern 839 into a functional gate structure indicated by a functional gate pattern 839a and a dielectric gate structure indicated by a non-function gate pattern 839b based on a CPODE process, the dummy transistor 862 in FIG. 8A is replaced by a non-functional device 864 with the dielectric gate structure (indicated by non-function gate pattern 839b) electrically isolated from the functional gate structure (indicated by function gate pattern 839a). In some embodiments, compared to dummy transistor 862, non-functional device 864 further reduces parasitic capacitance caused by the dummy transistor 862. As similarly described with reference to FIG. 2B, connecting the functional gate structure (indicated by function gate pattern 839a) to a metallization region of the M0 layer is still available through a via structure indicated by a via pattern 874 with the shortened CPODE pattern (e.g., non-function gate pattern 839b), even though connecting to a metallization region indicated by metallization track pattern 845 is no longer available due to the formation of the non-functional device 864.

FIG. 8C is a layout diagram 800C of various layout patterns corresponding to a portion of a third circuit cell example of a skewed logic circuit, in accordance with some embodiments. The third circuit cell example is a variation of the first circuit cell example. Therefore, components depicted in FIG. 8C that are the same or similar to those in FIG. 8A are given the same reference numbers, and detailed description thereof is simplified or omitted.

Compared with layout diagram 800A, layout diagram 800C includes the third circuit cell example that has six metallization regions in an M0 layer of the third circuit cell example, indicated by six metallization track patterns 881, 882, 884, 885, 886, and 887. In some embodiments, the metallization track pattern 881 corresponds to a metallization region for forming a first power rail configured to carry a first supply voltage (e.g., VDD). In some embodiments, the metallization track pattern 882 corresponds to a metallization region for forming a second power rail configured to carry a second supply voltage (e.g., VSS or the ground level). In this example, as the metallization region indicated by metallization track pattern 887 is likely reserved for being connected to the source/drain terminal indicated by contact patterns 858, the metallization regions indicated by metallization track patterns 884, 885, and 886 are still available for a via structure to land thereon for connecting the gate structure to M0 (e.g., a via pattern 876 indicative a via structure overlapping the metallization track pattern 884). As in FIG. 8C and similarly illustrated with reference to FIG. 8A, the dummy transistor 862 still introduces parasitic capacitance between the gate structure and the source/drain terminals (indicated by contact patterns 852 and 854).

FIG. 8D is a layout diagram 800D of various layout patterns corresponding to a portion of a fourth circuit cell example of a skewed logic circuit, in accordance with some embodiments. The fourth circuit cell example is a variation of the third circuit cell example. Components in FIG. 8D that are the same or similar to those in FIG. 8C are given the same reference numbers, and detailed description thereof is simplified or omitted.

In FIG. 8D, by converting the gate structure indicated by gate pattern 839 into a functional gate structure indicated by a functional gate pattern 839a and a dielectric gate structure indicated by a non-function gate pattern 839b based on a CPODE process, the dummy transistor 862 in FIG. 8C is replaced by a non-functional device 864 with the dielectric gate structure (indicated by non-function gate pattern 839b) electrically isolated from the functional gate structure (indicated by function gate pattern 839a). In some embodiments, compared to dummy transistor 862, non-functional device 864 further reduces parasitic capacitance. As similarly illustrated with reference to FIG. 2D, connecting the functional gate structure (indicated by function gate pattern 839a) to a metallization region of the M0 layer is still available through a via structure indicated by a via pattern 878 with the shortened CPODE pattern (e.g., non-function gate pattern 839b), even though connecting to the metallization regions indicated by metallization track patterns 884 and 885 is no longer available due to the formation of the non-functional device 864.

The examples in FIGS. 6A-8D are non-limiting examples. In some embodiments, the CPODE process and the CPO process are combinable to define one or more layout patterns of corresponding gate structures, regardless of the gate structures being functional or non-functional.

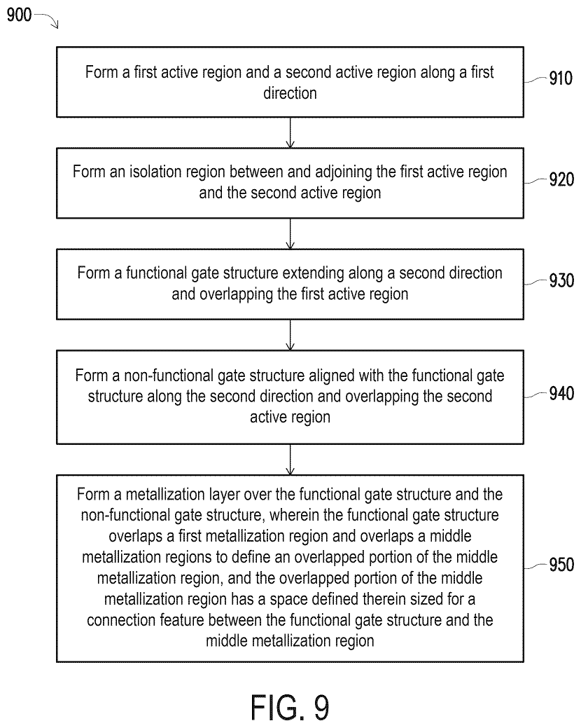

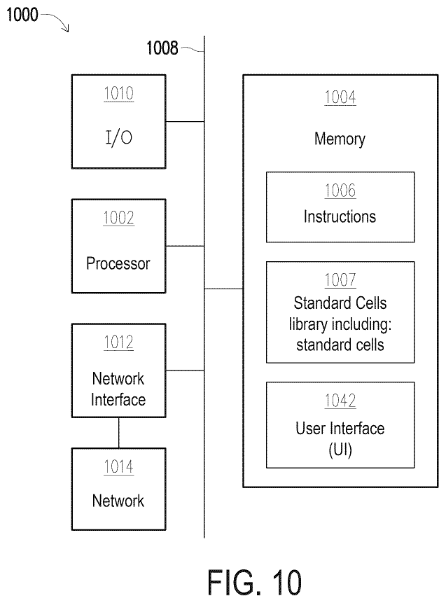

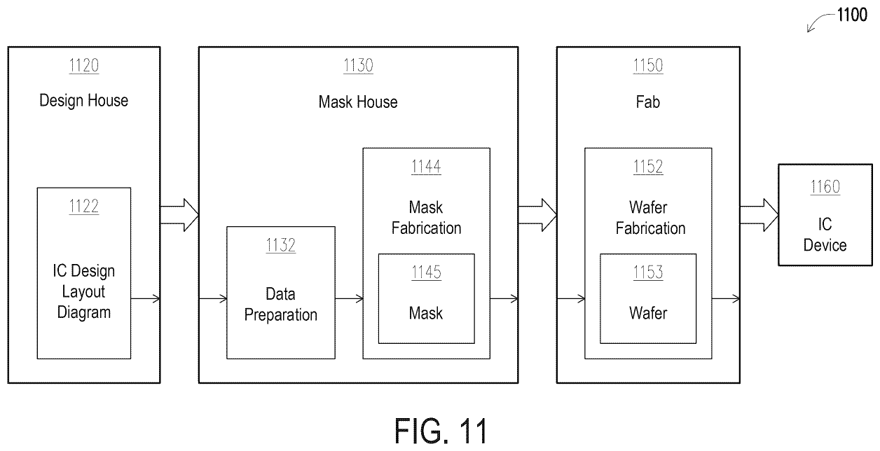

FIG. 9 is a flowchart of a method 900 of manufacturing a semiconductor structure, in accordance with some embodiments. In some embodiments, the semiconductor structure manufactured based on method 900 may include a circuit cell as illustrated based on the layout diagrams in FIGS. 2B, 2D, 3B, 3D, 4A-7B, 8B, and 8D. In some embodiments, method 900 corresponds to one or more operations performed based on, in whole or in part, a semiconductor device manufacturing system as illustrated in FIG. 11 in conjunction with an electronic design automation (EDA) system as illustrated in FIG. 10. As in FIG. 9, method 900 includes blocks 910-950.

At block 910, a first active region and a second active region extending along a first direction are formed. In some embodiments and as non-limiting examples, the first active region and the second active region correspond to any of the active regions indicated by active region patterns 212 and 214 in FIGS. 2A-3D, active region patterns 422 and 424 in FIGS. 4B-5C.

At block 920, an isolation region (e.g., indicated by blank region 216) between and adjoining the first active region and the second active region is formed. In some embodiments, the isolation region is formed based on masking a portion of a semiconductor substrate as the isolation region when forming the first active region and the second active region. In some embodiments, the isolation region is formed between the first active region and the second active region after the first active region and the second active region are formed.

At block 930, a functional gate structure extending along a second direction and overlapping the first active region is formed. In some embodiments and as non-limiting examples, the functional gate structure corresponds to any of the functional gate structures indicated by functional gate pattern 226c in FIGS. 2B and 2D, functional gate pattern 326c in FIGS. 3B and 3D, functional gate patterns 427a and 429a in FIGS. 4B-4D, and functional gate patterns 527a and 529a in FIGS. 5B-5C.

At block 940, a non-functional gate structure aligned with the functional gate structure along the second direction and overlapping the second active region is formed. In some embodiments and as non-limiting examples, the non-functional gate structure corresponds to any of the non-functional gate structures indicated by non-functional gate pattern 226d in FIGS. 2B and 2D, non-functional gate pattern 326d in FIGS. 3B and 3D, non-functional gate patterns 427b and 429b in FIGS. 4B-4D, and non-functional gate patterns 527b and 529b in FIGS. 5B-5C.

At block 950, a metallization layer is formed over the functional gate structure and the non-functional gate structure. In some embodiments, the metallization layer defines a first metallization region extending along the first direction over the first active region, a second metallization region extending along the first direction over the second active region, and one or two middle metallization regions extending along the first direction and between the first metallization region and the second metallization region. In some embodiments and as non-limiting examples, various metallization regions correspond to any of the metallization regions indicated by metallization track patterns 232, 234, and 236 in FIGS. 2B and 3B, metallization track patterns 231, 233, 235, and 237 in FIGS. 2D and 3D, metallization track patterns 442, 444, and 446 in FIGS. 4B and 5A, and metallization track patterns 462, 464, 466, and 468 in FIGS. 4C, 4D, 5B, and 5C.

In some embodiments, the functional gate structure overlaps the first metallization region and overlaps one of the one or two middle metallization regions to define an overlapped portion of the one of the one or two middle metallization regions. In some embodiments, the overlapped portion of the one of the one or two middle metallization regions has a space defined therein sized for a connection feature between the functional gate structure and the one of the one or two middle metallization regions.

In some embodiments, a distance between the overlapped portion and the first active region is less than a distance between the overlapped portion and the second active region. In some embodiments, the forming the non-functional gate structure is based on a continuous-poly-on-oxide-diffusion-edge (CPODE) process to form the non-functional gate structure that is a first dielectric gate structure adjoining the functional gate structure. In some embodiments, the forming the non-functional gate structure is based on a cut-poly (CPO) process to form the non-functional gate structure that is a second dielectric gate structure or a conductive gate structure spaced apart from the functional gate structure.

In some embodiments, a length of the non-functional gate structure within a cell region of the semiconductor structure and along the second direction is equal to or greater than a width of the second active region along the second direction. In some embodiments, the length of the non-functional gate structure along the second direction is less than one-half of a cell height of the cell region along the second direction.

In some embodiments, the one or two middle metallization regions include a third metallization region between the first metallization region and the second metallization region. In some embodiments, a width of the third metallization region is 1.2 to 2 times a width of the first metallization region. In some embodiments, the width of the third metallization region is 1.2 to 2 times a width of the second metallization region. In some embodiments, the one or two middle metallization regions further include a fourth metallization region between the third metallization region and the second metallization region.

In some embodiments, the method 900 further includes forming one or more channel structures within the first active region, the one or more channel structures being under or surrounded by the functional gate structure; forming a first drain/source structure within the first active region, the first drain/source structure being on a first side of the functional gate structure; and forming a second drain/source structure within the first active region, the second drain/source structure being on a second side of the functional gate structure. In some embodiments, a combination of the functional gate structure, the one or more channel structures, the first drain/source structure, and the second drain/source structure correspond to a planar FET, a FinFET, a nanosheet FET, a nanowire FET, or a CFET.

In some embodiments, block 950 includes forming a first conductive track of a metallization layer extending along the first direction, overlapping the functional gate structure, and overlapping the isolation region. In some embodiments, the method 900 further includes forming a connection feature connecting the functional gate structure and the first conductive track. In some embodiments, block 950 includes forming a second conductive track of the metallization layer extending along the first direction. In some embodiments, the second conductive track overlaps the first active region and is farther away from the second active region than the first conductive track. In some embodiments, the second conductive track overlaps the second active region and is farther away from the first active region than the first conductive track. In some embodiments, a width of the first conductive track is 1.2 to 2 times a width of the second conductive track.

In some embodiments, the method 900 may be modified for manufacturing a semiconductor structure. In some embodiments, the modified method of manufacturing the semiconductor structure includes forming a first active region and a second active region extending along a first direction, forming an isolation region between and adjoining the first active region and the second active region, forming a first functional gate structure extending along a second direction and overlapping the first active region, forming a first non-functional gate structure aligned with the first functional gate structure along the second direction and overlapping the second active region, forming a second functional gate structure extending along the second direction and overlapping the second active region, and forming a second functional gate structure extending along the second direction and overlapping the second active region. In some embodiments, the modified method further includes forming a first conductive track, a second conductive track, or both, of a metallization layer extending along the first direction and overlapping the isolation region, and forming a first connection feature connecting the first functional gate structure and the first conductive track. In some embodiments, modified method further includes forming a second connection feature connecting the second functional gate structure and the first conductive track, or connecting the second functional gate structure and the second conductive track.

In some embodiments, according to the modified method, a distance between the first connection feature and the first active region is less than a distance between the first connection feature and the second active region, and a distance between the second connection feature and the second active region is less than a distance between the second connection feature and the first active region.

FIG. 10 is a block diagram of an electronic design automation (EDA) system 1000 in accordance with some embodiments. In some embodiments, EDA system 1000 includes an automatic place and route (APR) system. Methods described herein of designing layout diagrams represent wire routing arrangements, in accordance with one or more embodiments, are implementable, for example, using EDA system 1000, in accordance with some embodiments.

In some embodiments, EDA system 1000 is a general purpose computing device including a hardware processor 1002 and a non-transitory, computer-readable storage medium 1004. Storage medium 1004, amongst other things, is encoded with, i.e., stores, computer program code 1006, where computer program code 1006 is a set of computer-executable instructions. Execution of computer program code 1006 by processor 1002 represents (at least in part) an EDA tool which implements a portion or all of, e.g., the methods described herein in accordance with one or more (hereinafter, the noted processes and/or methods).

Processor 1002 is electrically coupled to computer-readable storage medium 1004 via a bus 1008. Processor 1002 is also electrically coupled to an I/O interface 1010 by bus 1008. A network interface 1012 is also electrically connected to processor 1002 via bus 1008. Network interface 1012 is connected to a network 1014, so that processor 1002 and computer-readable storage medium 1004 are capable of connecting to external elements via network 1014. Processor 1002 is configured to execute computer program code 1006 encoded in computer-readable storage medium 1004 in order to cause EDA system 1000 to be usable for performing a portion or all of the noted processes and/or methods. In one or more embodiments, processor 1002 is a central processing unit (CPU), a multi-processor, a distributed processing system, an application specific integrated circuit (ASIC), and/or a suitable processing unit.

In one or more embodiments, computer-readable storage medium 1004 is an electronic, magnetic, optical, electromagnetic, infrared, and/or a semiconductor system (or apparatus or device). For example, computer-readable storage medium 1004 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable storage medium 1004 includes a compact disk-read only memory (CD-ROM), a compact disk-read/write (CD-R/W), and/or a digital video disc (DVD).

In one or more embodiments, storage medium 1004 stores computer program code 1006 configured to cause EDA system 1000 (where such execution represents (at least in part) the EDA tool) to be usable for performing a portion or all of the noted processes and/or methods. In one or more embodiments, storage medium 1004 also stores information which facilitates performing a portion or all of the noted processes and/or methods. In one or more embodiments, storage medium 1004 stores library 1007 of standard cells including such standard cells or any circuit cells corresponding to cells disclosed herein.

EDA system 1000 includes I/O interface 1010. I/O interface 1010 is coupled to external circuitry. In one or more embodiments, I/O interface 1010 includes a keyboard, keypad, mouse, trackball, trackpad, touchscreen, and/or cursor direction keys for communicating information and commands to processor 1002.

EDA system 1000 also includes network interface 1012 coupled to processor 1002. Network interface 1012 allows EDA system 1000 to communicate with network 1014, to which one or more other computer systems are connected. Network interface 1012 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more systems 1000.

EDA system 1000 is configured to receive information through I/O interface 1010. The information received through I/O interface 1010 includes one or more of instructions, data, design rules, libraries of standard cells, and/or other parameters for processing by processor 1002. The information is transferred to processor 1002 via bus 1008. EDA system 1000 is configured to receive information related to a UI through I/O interface 1010. The information is stored in computer-readable medium 1004 as user interface (UI) 1042.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by EDA system 1000. In some embodiments, a layout diagram which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

FIG. 11 is a block diagram of a semiconductor device (e.g., an integrated circuit (IC)) manufacturing system 1100, and an IC manufacturing flow associated therewith, in accordance with some embodiments. In some embodiments, based on a layout diagram, at least one of (i) one or more semiconductor masks or (ii) at least one component in a layer of a semiconductor device is fabricated using manufacturing system 1100.

In FIG. 11, manufacturing system 1100 includes entities, such as a design house 1120, a mask house 1130, and an IC manufacturer/fabricator (also referred as “fab”) 1150, that interact with one another in the design, development, and manufacturing cycles and/or services related to manufacturing an IC device 1160. The entities in system 1100 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 1120, mask house 1130, and IC fab 1150 are owned by a single larger company. In some embodiments, two or more of design house 1120, mask house 1130, and IC fab 1150 coexist in a common facility and use common resources.

Design house (or design team) 1120 generates an IC design layout diagram 1122. IC design layout diagram 1122 includes various geometrical patterns designed for an IC device 1160. The geometrical patterns correspond to patterns of metal, oxide, or semiconductor layers that make up the various components of IC device 1160 to be fabricated. The various layers combine to form various IC features. For example, a portion of IC design layout diagram 1122 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. Design house 1120 implements a proper design procedure to form IC design layout diagram 1122. The design procedure includes one or more of logic design, physical design or place and route. IC design layout diagram 1122 is presented in one or more data files having information of the geometrical patterns. For example, IC design layout diagram 1122 can be expressed in a GDSII file format or DFII file format.

Mask house 1130 includes data preparation 1132 and mask fabrication 1144. Mask house 1130 uses IC design layout diagram 1122 to manufacture one or more masks 1145 to be used for fabricating the various layers of IC device 1160 according to IC design layout diagram 1122. Mask house 1130 performs mask data preparation 1132, where IC design layout diagram 1122 is translated into a representative data file (“RDF”). Mask data preparation 1132 provides the RDF to mask fabrication 1144. Mask fabrication 1144 includes a mask writer. A mask writer converts the RDF to an image on a substrate, such as a mask (reticle) 1145 or a semiconductor wafer 1153. The design layout diagram 1122 is manipulated by mask data preparation 1132 to comply with particular characteristics of the mask writer and/or requirements of IC fab 1150. In FIG. 11, mask data preparation 1132 and mask fabrication 1144 are illustrated as separate elements. In some embodiments, mask data preparation 1132 and mask fabrication 1144 can be collectively referred to as mask data preparation.

In some embodiments, mask data preparation 1132 includes optical proximity correction (OPC) which uses lithography enhancement techniques to compensate for image errors, such as those that can arise from diffraction, interference, other process effects and the like. OPC adjusts IC design layout diagram 1122. In some embodiments, mask data preparation 1132 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 1132 includes a mask rule checker (MRC) that checks the IC design layout diagram 1122 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 1122 to compensate for limitations during mask fabrication 1144, which may undo part of the modifications performed by OPC in order to meet mask creation rules.

In some embodiments, mask data preparation 1132 includes lithography process checking (LPC) that simulates processing that will be implemented by IC fab 1150 to fabricate IC device 1160. LPC simulates this processing based on IC design layout diagram 1122 to create a simulated manufactured device, such as IC device 1160. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout diagram 1122.

It should be understood that the above description of mask data preparation 1132 has been simplified for the purposes of clarity. In some embodiments, data preparation 1132 includes additional features such as a logic operation (LOP) to modify the IC design layout diagram 1122 according to manufacturing rules. Additionally, the processes applied to IC design layout diagram 1122 during data preparation 1132 may be executed in a variety of different orders.

After mask data preparation 1132 and during mask fabrication 1144, a mask 1145 or a group of masks 1145 are fabricated based on the modified IC design layout diagram 1122. In some embodiments, mask fabrication 1144 includes performing one or more lithographic exposures based on IC design layout diagram 1122. In some embodiments, an electron-beam (e-beam) or a mechanism of multiple e-beams is used to form a pattern on a mask (photomask or reticle) 1145 based on the modified IC design layout diagram 1122. Mask 1145 can be formed in various technologies. In some embodiments, mask 1145 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask version of mask 1145 includes a transparent substrate (e.g., fused quartz) and an opaque material (e.g., chromium) coated in the opaque regions of the binary mask. In another example, mask 1145 is formed using a phase shift technology. In a phase shift mask (PSM) version of mask 1145, various features in the pattern formed on the phase shift mask are configured to have proper phase difference to enhance the resolution and imaging quality. In various examples, the phase shift mask can be attenuated PSM or alternating PSM. The mask(s) generated by mask fabrication 1144 is used in a variety of processes. For example, such a mask(s) is used in an ion implantation process to form various doped regions in semiconductor wafer 1153, in an etching process to form various etching regions in semiconductor wafer 1153, and/or in other suitable processes.

IC fab 1150 includes wafer fabrication 1152. IC fab 1150 is an IC fabrication business that includes one or more manufacturing facilities for the fabrication of a variety of different IC products. In some embodiments, IC fab 1150 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

IC fab 1150 uses mask(s) 1145 fabricated by mask house 1130 to fabricate IC device 1160. Thus, IC fab 1150 at least indirectly uses IC design layout diagram 1122 to fabricate IC device 1160. In some embodiments, semiconductor wafer 1153 is fabricated by IC fab 1150 using mask(s) 1145 to form IC device 1160. In some embodiments, the IC fabrication includes performing one or more lithographic exposures based at least indirectly on IC design layout diagram 1122. Semiconductor wafer 1153 includes a silicon substrate or other proper substrate having material layers formed thereon. Semiconductor wafer 1153 further includes one or more of various doped regions, dielectric features, multilevel interconnects, and the like (formed at subsequent manufacturing steps).

It will be readily seen by one of ordinary skill in the art that one or more of the disclosed embodiments fulfill one or more of the advantages set forth above. After reading the foregoing specification, one of ordinary skill will be able to affect various changes, substitutions of equivalents and various other embodiments as broadly disclosed herein. It is therefore intended that the protection granted hereon be limited only by the definition contained in the appended claims and equivalents thereof.

In some embodiments, a semiconductor structure includes a first active region and a second active region extending along a first direction, an isolation region between and adjoining the first active region and the second active region, a functional gate structure extending along a second direction and overlapping the first active region, a non-functional gate structure aligned with the functional gate structure along the second direction and overlapping the second active region, and a metallization layer over the functional gate structure and the non-functional gate structure. In some embodiments, the metallization layer defines a first metallization region extending along the first direction over the first active region, a second metallization region extending along the first direction over the second active region, and one or two middle metallization regions extending along the first direction and between the first metallization region and the second metallization region. In some embodiments, the functional gate structure overlaps the first metallization region and overlaps one of the one or two middle metallization regions to define an overlapped portion of the one of the one or two middle metallization regions. In some embodiments, the overlapped portion of the one of the one or two middle metallization regions has a space defined therein sized for a connection feature between the functional gate structure and the one of the one or two middle metallization regions.

In some embodiments, a semiconductor structure includes a first active region and a second active region extending along a first direction, an isolation region between and adjoining the first active region and the second active region, a functional gate structure extending along a second direction and overlapping the first active region, and a non-functional gate structure aligned with the functional gate structure along the second direction and overlapping the second active region. In some embodiments, the semiconductor structure includes a first conductive track of a metallization layer extending along the first direction, overlapping the functional gate structure, and overlapping the isolation region. In some embodiments, the semiconductor structure includes a connection feature connecting the functional gate structure and the first conductive track.

In some embodiments, a semiconductor structure includes a first active region and a second active region extending along a first direction, an isolation region between and adjoining the first active region and the second active region, a first functional gate structure extending along a second direction and overlapping the first active region, a first non-functional gate structure aligned with the first functional gate structure along the second direction and overlapping the second active region, a second functional gate structure extending along the second direction and overlapping the second active region, and a second non-functional gate structure aligned with the second functional gate structure along the second direction and overlapping the first active region. In some embodiments, the semiconductor structure includes a first conductive track, a second conductive track, or both, of a metallization layer extending along the first direction and overlapping the isolation region. In some embodiments, the semiconductor structure includes a first connection feature connecting the first functional gate structure and the first conductive track. In some embodiments, the semiconductor structure includes a second connection feature connecting the second functional gate structure and the first conductive track, or connecting the second functional gate structure and the second conductive track.

In some embodiments, a method of manufacturing a semiconductor structure includes forming a first active region and a second active region extending along a first direction, forming an isolation region between and adjoining the first active region and the second active region, forming a functional gate structure extending along a second direction and overlapping the first active region, forming a non-functional gate structure aligned with the functional gate structure along the second direction and overlapping the second active region, and forming a metallization layer over the functional gate structure and the non-functional gate structure. In some embodiments, the metallization layer defines a first metallization region extending along the first direction over the first active region, a second metallization region extending along the first direction over the second active region, and one or two middle metallization regions extending along the first direction and between the first metallization region and the second metallization region. In some embodiments, the functional gate structure overlaps the first metallization region and overlaps one of the one or two middle metallization regions to define an overlapped portion of the one of the one or two middle metallization regions. In some embodiments, the overlapped portion of the one of the one or two middle metallization regions has a space defined therein sized for a connection feature between the functional gate structure and the one of the one or two middle metallization regions.

In some embodiments, a method of manufacturing a semiconductor structure includes forming a first active region and a second active region extending along a first direction, forming an isolation region between and adjoining the first active region and the second active region, forming a functional gate structure extending along a second direction and overlapping the first active region, and forming a non-functional gate structure aligned with the functional gate structure along the second direction and overlapping the second active region. In some embodiments, the method of manufacturing the semiconductor structure includes forming a first conductive track of a metallization layer extending along the first direction, overlapping the functional gate structure, and overlapping the isolation region. In some embodiments, the method of manufacturing the semiconductor structure includes forming a connection feature connecting the functional gate structure and the first conductive track.

In some embodiments, a method of manufacturing a semiconductor structure includes forming a first active region and a second active region extending along a first direction, forming an isolation region between and adjoining the first active region and the second active region, forming a first functional gate structure extending along a second direction and overlapping the first active region, forming a first non-functional gate structure aligned with the first functional gate structure along the second direction and overlapping the second active region, forming a second functional gate structure extending along the second direction and overlapping the second active region, and forming a second non-functional gate structure aligned with the second functional gate structure along the second direction and overlapping the first active region. In some embodiments, the method of manufacturing the semiconductor structure includes forming a first conductive track, a second conductive track, or both, of a metallization layer extending along the first direction and overlapping the isolation region. In some embodiments, the method of manufacturing the semiconductor structure includes forming a first connection feature connecting the first functional gate structure and the first conductive track. In some embodiments, the method of manufacturing the semiconductor structure includes forming a second connection feature connecting the second functional gate structure and the first conductive track, or connecting the second functional gate structure and the second conductive track.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure and that they may make various changes, substitutions, and alterations herein without departing from the spirit and scope of the present disclosure.

What is claimed is:

1. A semiconductor structure, comprising:
a first active region and a second active region extending along a first direction and isolated from each other;
a functional gate structure extending along a second direction and overlapping the first active region;
a non-functional gate structure aligned with the functional gate structure along the second direction and overlapping the second active region; and
a metallization layer over the functional gate structure and the non-functional gate structure, the metallization layer defining a first metallization region extending along the first direction over the first active region, a second metallization region over the second active region, and at least one middle metallization region extending along the first direction and between the first metallization region and the second metallization region,
wherein
the functional gate structure overlaps the first metallization region and overlaps the at least one middle metallization region to define an overlapped portion of the at least one middle metallization region, and
the overlapped portion of the at least one middle metallization region has a space sized for a connection feature between the functional gate structure and the at least one middle metallization region.

2. The semiconductor structure of claim 1, wherein a distance between the overlapped portion and the second active region is greater than or equal to a distance between the overlapped portion and the first active region.

3. The semiconductor structure of claim 1, wherein
the non-functional gate structure is a first dielectric gate structure adjoining the functional gate structure, or
the non-functional gate structure is a second dielectric gate structure or a conductive gate structure spaced apart from the functional gate structure.

4. The semiconductor structure of claim 1, wherein
a width of the second active region along the second direction is less than a length of the non-functional gate structure within a cell region of the semiconductor structure and along the second direction, and
the length of the non-functional gate structure along the second direction is less than one-half of a cell height of the cell region along the second direction.

5. The semiconductor structure of claim 1, wherein
the at least one middle metallization region includes a third metallization region between the first metallization region and the second metallization region.

6. The semiconductor structure of claim 5, wherein
a width of the first metallization region or a width of the second metallization region is 0.5 to 0.83 times a width of the third metallization region.

7. The semiconductor structure of claim 5, wherein
the at least one middle metallization region further includes a fourth metallization region between the third metallization region and the second metallization region.

8. The semiconductor structure of claim 1, further comprising:
one or more channel structures within the first active region, the one or more channel structures being under or surrounded by the functional gate structure;
a first drain/source structure within the first active region and on a first side of the functional gate structure; and
a second drain/source structure within the first active region and on a second side of the functional gate structure,
wherein a combination of the functional gate structure, the one or more channel structures, the first drain/source structure, and the second drain/source structure corresponds to a planar field effect transistor (FET), a fin FET (FinFET), a nanosheet FET, or a nanowire FET.

9. A semiconductor structure, comprising:
a first active region and a second active region extending along a first direction and isolated from each other;
a first functional gate structure extending along a second direction and overlapping the first active region;
a first non-functional gate structure aligned with the first functional gate structure along the second direction and overlapping the second active region;
a second functional gate structure extending along the second direction and overlapping the second active region;
a second non-functional gate structure aligned with the second functional gate structure along the second direction and overlapping the first active region;
a first conductive track, a second conductive track, or a combination of the first conductive track and the second conductive track of a metallization layer extending along the first direction; and
a first connection feature connecting the first functional gate structure and the first conductive track, and a second connection feature connecting the second functional gate structure and the first conductive track or the second connection feature connecting the second functional gate structure and the second conductive track.

10. The semiconductor structure of claim 9,
wherein a distance between the first connection feature and the first active region is less than a distance between the first connection feature and the second active region, and
wherein a distance between the second connection feature and the second active region is less than a distance between the second connection feature and the first active region.

11. The semiconductor structure of claim 9, further comprising:
a third conductive track,
wherein the third conductive track overlaps the first active region and is farther away from the second active region than the first conductive track,
wherein the second connection feature connects the second functional gate structure and the first conductive track, and
wherein a width of the third conductive track is 0.5 to 0.83 times a width of the first conductive track.

12. The semiconductor structure of claim 9, wherein the second connection feature connects the second functional gate structure and the second conductive track, the semiconductor structure further comprising:
a third conductive track of another metallization layer extending along the second direction;
a third connection feature connecting the first conductive track and the third conductive track; and
a fourth connection feature connecting the second conductive track and the third conductive track.

13. The semiconductor structure of claim 9,
wherein the first non-functional gate structure is one of:
a first dielectric gate structure adjoining the first functional gate structure;
a second dielectric gate structure spaced apart from the first functional gate structure; or
a first conductive gate structure spaced apart from the first functional gate structure, and
wherein the second non-functional gate structure is one of:
a third dielectric gate structure adjoining the second functional gate structure;
a fourth dielectric gate structure spaced apart from the second functional gate structure; or
a second conductive gate structure spaced apart from the second functional gate structure.

14. The semiconductor structure of claim 9, further comprising:
one or more channel structures within the first active region, the one or more channel structures being under or surrounded by the first functional gate structure;
a first drain/source structure within the first active region and on a first side of the first functional gate structure; and
a second drain/source structure within the first active region and on a second side of the first functional gate structure,
wherein a combination of the first functional gate structure, the one or more channel structures, the first drain/source structure, and the second drain/source structure corresponds to a planar FET, a FinFET, a nanosheet FET, a nanowire FET, or a complementary FET (CFET).

15. A method of manufacturing a semiconductor structure, comprising:
forming a first active region and a second active region extending along a first direction and isolated from each other;
forming a functional gate structure extending along a second direction and overlapping the first active region;
forming a non-functional gate structure aligned with the functional gate structure along the second direction and overlapping the second active region; and
forming a metallization layer over the functional gate structure and the non-functional gate structure, the metallization layer defining a first metallization region extending along the first direction over the first active region, a second metallization region over the second active region, and at least one middle metallization region extending along the first direction and between the first metallization region and the second metallization region,
wherein
the functional gate structure overlaps the first metallization region and overlaps the at least one middle metallization region to define an overlapped portion of the at least one middle metallization region, and
the overlapped portion of the at least one middle metallization region has a space sized for a connection feature between the functional gate structure and the at least one middle metallization region.

16. The method of claim 15, wherein a distance between the overlapped portion and the first active region is less than a distance between the overlapped portion and the second active region.

17. The method of claim 15, wherein the forming the non-functional gate structure is based on
a continuous-poly-on-oxide-diffusion-edge (CPODE) process to form the non-functional gate structure that is a first dielectric gate structure adjoining the functional gate structure, or
a cut-poly (CPO) process to form the non-functional gate structure that is a second dielectric gate structure or a conductive gate structure spaced apart from the functional gate structure.

18. The method of claim 15, wherein
a width of the second active region along the second direction is less than a length of the non-functional gate structure within a cell region of the semiconductor structure and along the second direction, and
the length of the non-functional gate structure along the second direction is less than one-half of a cell height of the cell region along the second direction.

19. The method of claim 15, wherein
the at least one middle metallization region includes a third metallization region between the first metallization region and the second metallization region, and
a width of the first metallization region or a width of the second metallization region is 0.5 to 0.83 times a width of the third metallization region.

20. The method of claim 15, further comprises:
forming one or more channel structures within the first active region, the one or more channel structures being under or surrounded by the functional gate structure;
forming a first drain/source structure within the first active region, the first drain/source structure being on a first side of the functional gate structure; and
forming a second drain/source structure within the first active region, the second drain/source structure being on a second side of the functional gate structure,
wherein a combination of the functional gate structure, the one or more channel structures, the first drain/source structure, and the second drain/source structure corresponds to a planar field effect transistor (FET), a fin FET (FinFET), a nanosheet FET, or a nanowire FET.
